(19) United States
(12) Patent Application Publication
(10) Pub. No.: US 2025/0299748 A1
(43) Pub. Date: Sep. 25, 2025

(54) MEMORY DEVICE

(71) Applicant: Kioxia Corporation, Tokyo (JP)

(72) Inventors: Taisei YOSHINAGA, Hiratsuka (JP); Yoshinao SUZUKI, Yokohama (JP); Takatoshi MINAMOTO, Kamakura (JP)

(73) Assignee: Kioxia Corporation, Tokyo (JP)

(21) Appl. No.: 19/055,784

(22) Filed: Feb. 18, 2025

(30) Foreign Application Priority Data
Mar. 22, 2024 (JP) 2024-046344

(51) Int. Cl. G11C 16/30; G11C 5/14; G11C 16/08; G11C 16/12

(52) U.S. Cl. CPC G11C 16/30; G11C 5/145; G11C 5/147; G11C 16/08; G11C 16/12

(57) ABSTRACT

According to one embodiment, a memory device includes: a memory cell array including a plurality of memory cells; and a voltage generator that is supplied with a first external voltage and a second external voltage higher than the first external voltage and generates an operating voltage of the memory cell array. An operation mode of the voltage generator at a time of generating a first voltage value of the operating voltage includes a first mode including a first period and a second period after the first period, and the first mode of generating the operating voltage using the first external voltage in the first period and using the second external voltage in the second period.

### CROSS-REFERENCE TO RELATED APPLICATIONS

This application is based upon and claims the benefit of priority from Japanese Patent Application No. 2024-046344, filed Mar. 22, 2024, the entire contents of which are incorporated herein by reference.

### FIELD

Embodiments described herein relate generally to a memory device.

### BACKGROUND

A NAND flash memory capable of storing data in a non-volatile manner is known.

### BRIEF DESCRIPTION OF THE DRAWINGS

FIG. 1 is a block diagram illustrating a system including a memory device of a first embodiment.

FIG. 2 is a circuit diagram illustrating a configuration example of a memory cell array of the memory device of the first embodiment.

FIG. 3 is a cross-sectional view illustrating a structure example of the memory cell array of the memory device of the first embodiment.

FIG. 4 is a cross-sectional view illustrating a structure example of a memory pillar of the memory device of the first embodiment.

FIG. 5 is a diagram illustrating a relationship between data and a threshold voltage of a memory cell.

FIG. 6 is a circuit diagram illustrating a configuration example of a voltage generator of the memory device of the first embodiment.

FIG. 7 is a cross-sectional view illustrating a configuration example of elements of the voltage generator of the memory device of the first embodiment.

FIG. 8 is a diagram illustrating operation modes of the voltage generator of the memory device of the first embodiment.

FIG. 9 is a diagram for explaining an operation example of the memory device of the first embodiment.

FIG. 10 is a diagram for explaining an operation example of the memory device of the first embodiment.

FIG. 11 is a diagram for explaining an operation example of the memory device of the first embodiment.

FIG. 12 is a diagram for explaining an operation example of the memory device of the first embodiment.

FIG. 13 is a diagram illustrating a verification result of the memory device of the first embodiment.

FIG. 14 is a diagram illustrating a verification result of the memory device of the first embodiment.

FIG. 15 is a diagram illustrating a verification result of the memory device of the first embodiment.

FIG. 16 is a diagram illustrating a verification result of the memory device of the first embodiment.

FIG. 17 is a circuit diagram illustrating a configuration example of a memory device of a second embodiment.

FIG. 18 is a circuit diagram illustrating a configuration example of the memory device of a second embodiment.

FIG. 19 is a diagram for explaining an operation example of the memory device of the second embodiment.

FIG. 20 is a diagram for explaining an operation example of the memory device of the second embodiment.

FIG. 21 is a circuit diagram illustrating a configuration example of a memory device of a third embodiment.

FIG. 22 is a diagram for explaining an operation example of the memory device of the third embodiment.

FIG. 23 is a diagram for explaining an operation example of the memory device of the third embodiment.

FIG. 24 is a cross-sectional view illustrating a modification of the memory device of the embodiments.

### DETAILED DESCRIPTION

In general, according to one embodiment, a memory device includes: a memory cell array including a plurality of memory cells; and a voltage generator that is supplied with a first external voltage and a second external voltage higher than the first external voltage and generates an operating voltage of the memory cell array, wherein an operation mode of the voltage generator at a time of generating a first voltage value of the operating voltage includes a first mode including a first period and a second period after the first period, and the first mode of generating the operating voltage using the first external voltage in the first period and using the second external voltage in the second period.

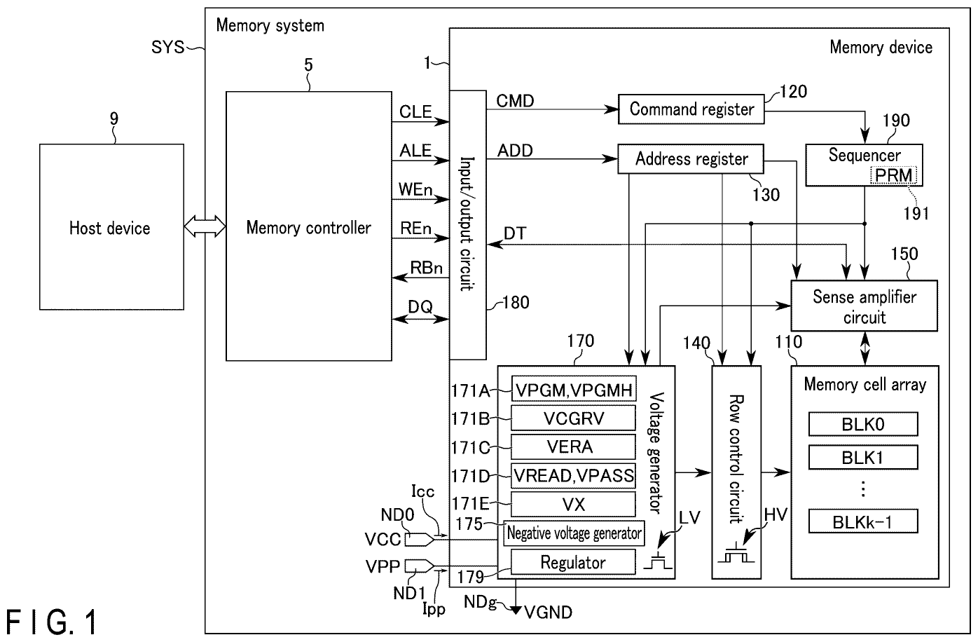

Memory devices of embodiments will be described with reference to FIGS. 1 to 24. In the following description, elements having the same function and configuration are denoted by the same reference numerals. Also, in each of the following embodiments, components (for example, circuits, wirings, and various voltages and signals) having reference signs with numbers/letters at the ends for distinguishing are not necessarily distinguished from each other, a description (reference sign) in which the numbers/letters at the ends are omitted is used.

### (1) First Embodiment

A memory device and a method of controlling the memory device of a first embodiment will be described with reference to FIGS. 1 to 16.

### (a) Configuration Example

A configuration example of the memory device of the first embodiment will be described with reference to FIGS. 1 to 8.

FIG. 1 is a block diagram for explaining a configuration example of a memory system SYS including a memory device 1 of the present embodiment.

As illustrated in FIG. 1, the memory system SYS is connected to a host device 9 via a host bus. The memory system SYS can be requested from the host device 9 to write data, read data, and erase data.

The host device 9 is, for example, a personal computer, an embedded device, a server, or the like. The embedded device is, for example, a smartphone, a mobile terminal, or a digital camera. The host bus is a bus based on an interface standard such as an SD™ interface, a serial attached SCSI (small computer system interface) (SAS), a serial ATA (advanced technology attachment) (SATA), a peripheral component interconnect express (PCIe), or a non-volatile memory express (NVMe). The memory system SYS may be connected to the host device 9 by wireless communication.

The memory system SYS includes the memory device 1 of the present embodiment and a memory controller 5.

The memory controller 5 is electrically coupled to the memory device 1. The memory controller 5 transmits a command CMD, an address ADD, data DT, and a plurality of control signals to the memory device 1.

The memory device 1 is a nonvolatile semiconductor memory device. For example, the memory device 1 of the present embodiment is a NAND flash memory.

The memory device 1 receives the command CMD, the address ADD, the data DT, and the control signals. The data DT is transferred between the memory device 1 and the memory controller 5. Hereinafter, the data DT transferred from the memory controller 5 to the memory device 1 at a time of a write sequence is referred to as write data. The write data DT is written in the memory device 1. At the time of a read sequence, the data DT transferred from the memory device 1 to the memory controller 5 is referred to as read data. The read data DT is read from the memory device 1.

The memory device 1 includes, for example, a memory cell array 110, a command register 120, an address register 130, a row control circuit 140, a sense amplifier circuit 150, a voltage generator 170, an input/output circuit 180, and a sequencer 190.

The memory cell array 110 stores data. A plurality of bit lines and a plurality of word lines are provided in the memory cell array 110. The memory cell array 110 includes a plurality of blocks BLK (BLK0, . . . , and BLKk−1). Each block BLK is an aggregate of a plurality of memory cells. Each memory cell is associated with a bit line and a word line. The memory cell array 110 includes a plurality of select gate lines for selecting a control unit in the memory cell array 110. An internal configuration of the memory cell array 110 will be described later.

The command register 120 temporarily stores the command CMD from the memory controller 5. The command CMD is, for example, a signal including an order for causing the sequencer 190 to execute the read sequence, the write sequence, an erase sequence, and the like.

The address register 130 temporarily stores the address (selected address) ADD from the memory controller 5. The address ADD includes, for example, a block address, a page address (word line address), a column address, and the like. The block address, the page address, and the column address are used to select the block BLK, the word line, and the bit line (column), respectively. Hereinafter, the block selected based on the block address is referred to as selected block. The word line selected based on the page address is referred to as selected word line.

The row control circuit 140 controls an operation related to a row of the memory cell array 110. The row control circuit 140 selects a block BLK in the memory cell array 110 based on the block address. For example, the row control circuit 140 transfers a voltage applied to an interconnect corresponding to the selected word line to the selected word line in the selected block BLK. The row control circuit 140 controls selection (activation) and non-selection (deactivation) of the select gate line based on the address ADD. The row control circuit 140 includes a transfer gate HV of a high breakdown voltage transistor. The transfer gate HV transfers a voltage generated by the voltage generator 170 which will be described later to an interconnect in the memory cell array 110. The transfer gate (high breakdown voltage transistor) HV has a breakdown voltage of 10 V or more, more specifically, a breakdown voltage (for example, an insulation breakdown voltage) of about 20 V to 30 V.

The sense amplifier circuit 150 controls an operation related to a column of the memory cell array 110. In the write sequence, the sense amplifier circuit 150 applies a voltage to each of the bit lines provided in the memory cell array 110 according to the write data DT from the memory controller 5. In the read sequence, the sense amplifier circuit 150 determines the data stored in the memory cell based on the presence or absence of generation of a current in the bit line or a variation in potential of the bit line. The sense amplifier circuit 150 transfers data based on the determination result to the memory controller 5 as the read data DT. The sense amplifier circuit 150 includes a sense amplifier unit, a data latch circuit, a cache circuit, and the like.

The voltage generator 170 generates and outputs a plurality of voltages (hereinafter, also referred to as operating voltages) for various operations of the memory device 1. The voltage generator 170 receives an external voltage VCC and an external voltage VPP from the outside of the memory device 1. The voltage generator 170 receives a ground voltage VGND from the outside of the memory device 1. The voltage generator 170 generates an operating voltage having a desired voltage value using at least one of the external voltage VCC and the external voltage VPP. The external voltage VCC is supplied to a voltage node (external voltage terminal) ND0. The external voltage VPP is supplied to a voltage node ND1. The ground voltage VGND is supplied to a voltage node NDg. The external voltages VCC and VPP are higher than the ground voltage VGND and have positive voltage values. The voltage value of the external voltage VPP is higher than the voltage value of the external voltage VCC. For example, the external voltage VCC has a voltage value of about 2.5 V to 3.3 V. For example, the external voltage VPP has a voltage value of about 6 V to 12 V. As a more specific example, the external voltage VPP has a voltage value within a voltage range of about 12 V±10%. The external voltage VPP may have a voltage value higher than 12 V. The ground voltage VGND has a voltage value of about 0 V. Depending on the usage environment of the memory system SYS, the external voltage VPP may not be supplied to the voltage generator 170.

A current Icc according to the external voltage VCC flows to the voltage node ND0, and a current Ipp according to the external voltage VPP flows to the voltage node ND1.

The voltage generator 170 includes a plurality of charge pump circuits 171 (171A, 171B, 171C, 171D, and 171E), a negative voltage generator 175, and a regulator 179.

The charge pump circuits 171 output a voltage having a positive voltage value. The charge pump circuits 171 generate voltages in different ranges (voltage values). Each charge pump circuit 171 boosts the voltage VCC by a plurality of booster stages (pump stages) to generate a desired voltage. The charge pump circuit 171A generates a program voltage VPGM to be supplied to the selected word line during a program operation and a voltage VPGMH equal to or higher than the program voltage VPGM. The charge pump circuit 171B generates a read voltage VCGRV to be supplied to the selected word line during a read operation. The charge pump circuit 171C generates an erase voltage VERA to be applied to the word line during an erase operation. The charge pump circuit 171D generates a non-selected voltage VREAD to be supplied to a non-selected word line during the read operation and a verify operation and a non-selected voltage VPASS to be supplied to the non-selected word line during the program operation. The charge pump circuit 171E generates a voltage VX to be supplied to the sense amplifier circuit 150. Hereinafter, various voltages generated by each of the charge pump circuits 171 are also referred to as charge pump voltages.

The negative voltage generator 175 generates an operating voltage having a negative voltage value. The negative voltage generator 175 generates an operating voltage having a negative voltage value using the external voltage VCC.

The regulator 179 receives the voltage output from the charge pump circuit 171 and the external voltage VPP. The regulator 179 adjusts the magnitude of the voltage output from the charge pump circuit 171 and the magnitude of the supplied external voltage VPP. For example, the regulator 179 can step down the external voltage VPP to generate an operating voltage having a certain voltage value. Hereinafter, the voltage output from the regulator 179 is also referred to as regulator voltage. The regulator 179 can be provided inside each charge pump circuit 171 as a component of the charge pump circuit 171.

For example, the voltage generator 170 includes a low breakdown voltage transistor LV. The low breakdown voltage transistor LV has a breakdown voltage (for example, an insulation breakdown voltage) of about 3 V to 5 V.

The input/output circuit 180 functions as an interface circuit on the memory device 1 side between the memory device 1 and the memory controller 5. In a case where the memory device 1 is a NAND flash memory, the input/output circuit 180 communicates with the memory controller 5 based on a NAND interface standard such as open NAND flash interface (ONFI). A command latch enable signal CLE, an address latch enable signal ALE, a write enable signal WEn, a read enable signal REn, a ready/busy signal RBn, an input/output signal DQ, and the like are used for communication between the memory device 1 and the memory controller 5.

The command latch enable signal CLE is a signal indicating that the input/output signal DQ received by the memory device 1 is the command CMD. The address latch enable signal ALE is a signal indicating that the input/output signal DQ received by the memory device 1 is the address ADD. The write enable signal WEn is a signal for ordering the memory device 1 to input the input/output signal DQ (data write operation). The read enable signal REn is a signal ordering the memory device 1 to output the input/output signal DQ from the memory device 1 to the memory controller 5 (host device 9).

The ready/busy signal RBn is a signal notifying, from the memory device 1 to the memory controller 5, whether the memory device 1 is in a ready state of accepting an order from the memory controller 5 or in a busy state of not accepting an order.

The input/output signal DQ is, for example, a signal set having an 8-bit width. The input/output signal DQ may include the command CMD, the address ADD, the data DT, and the like.

The sequencer 190 controls the entire operation of the memory device 1. The sequencer 190 controls each circuit based on the command CMD in the command register 120. For example, the sequencer 190 holds a parameter PRM for controlling the operation of the memory device 1 in the register 191. The parameter PRM is read from a read only memory (ROM) block in the memory device 1 to the register 191 in the sequencer 190 when the memory device 1 (and the memory system SYS) is turned on. The parameter PRM may be supplied from the memory controller 5 to the memory device 1.

For example, a control unit called a plane may be provided in the memory device 1. A plane includes the memory cell array 110, the row control circuit 140, and the sense amplifier circuit 150. In the example of FIG. 1, the memory device 1 includes a plane. The memory device 1 may include a plurality of planes.

(a-1) Memory Cell Array

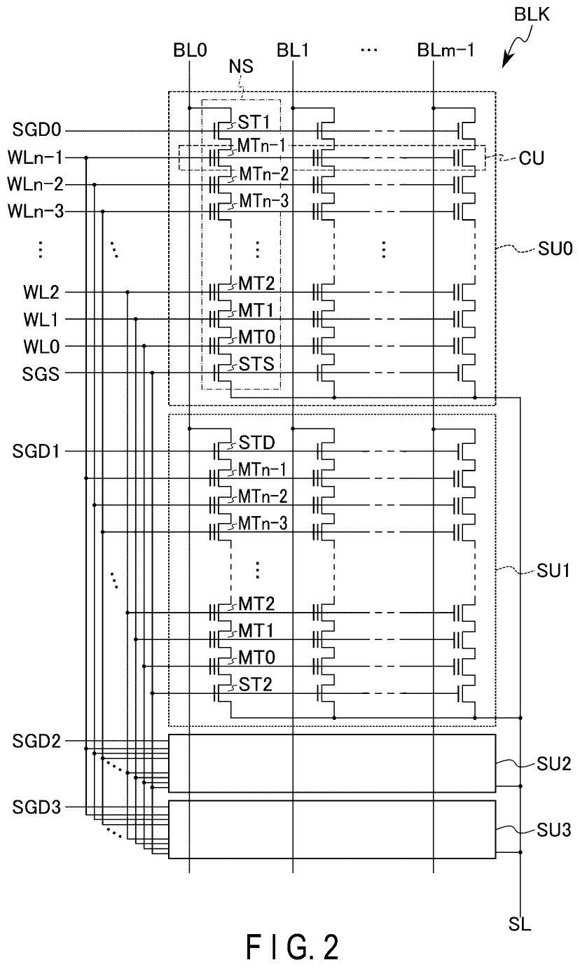

FIG. 2 is a circuit diagram illustrating a circuit configuration of a certain block BLK in the memory cell array 110 in the memory device 1 of the present embodiment.

As illustrated in FIG. 2, when the memory device 1 is a NAND flash memory, a block BLK includes a plurality of (for example, four) string units SU (SU0, . . . , and SU3). Each string unit SU includes a plurality of NAND strings NS. The number of blocks BLK in the memory cell array 110, the number of string units SU in the block BLK, and the number of NAND strings NS in the string unit SU are arbitrary.

Each NAND string NS includes a plurality of memory cells MT (MT0, MT1, MT2, . . . , MTn−3, MTn−2, and MTn−1) and a plurality of select transistors ST1 and ST2. n is a natural number of 2 or more. The memory cells MT are connected in series between a source of the select transistor ST1 and a drain of the select transistor ST2.

The memory cell (also referred to as memory cell transistor) MT is a field effect transistor having a control gate and a charge storage layer. The memory cell MT stores data of 1 bit or more in a substantially non-volatile manner.

Gates of the select transistors ST1 in the string units SU0, . . . , and SU3 are respectively connected to corresponding drain-side select gate lines SGD among a plurality of drain-side select gate lines SGD (SGD0, . . . , and SGD3).

Gates of the select transistors ST2 in each of the string units SU0, . . . , and SU3 are commonly connected to, for example, a source-side select gate line SGS. The gate of the select transistor ST2 may be connected to a different source-side select gate line SGS for each of the string units SU0, . . . , and SU3.

Control gates of the memory cells MT0, . . . , and MTn−1 belonging to the same block BLK are each connected to a corresponding word line WL among the word lines WL (WL0, WL1, WL2, . . . , WLn−3, WLn−2, and WLn−1).

The drains of the select transistors ST1 of the NAND strings NS belonging to the same column in the memory cell array 110 are each connected to a corresponding bit line BL among a plurality of bit lines BL (BL0, BL1, . . . , and BLm−1). m is a natural number of 2 or more.

The sources of the select transistors ST2 are commonly connected to a source line SL.

The string unit SU is an aggregate of NAND strings NS connected to different bit lines BL and connected to the same drain-side select gate line SGD. The block BLK is an aggregate of the string units SU sharing the word lines WL. The memory cell array 110 is an aggregate of the blocks BLK sharing the bit lines BL.

Hereinafter, in the string units SU, an aggregate of the memory cells MTs (memory cell group) commonly connected to the same word line WL is also referred to as cell unit CU (or memory group).

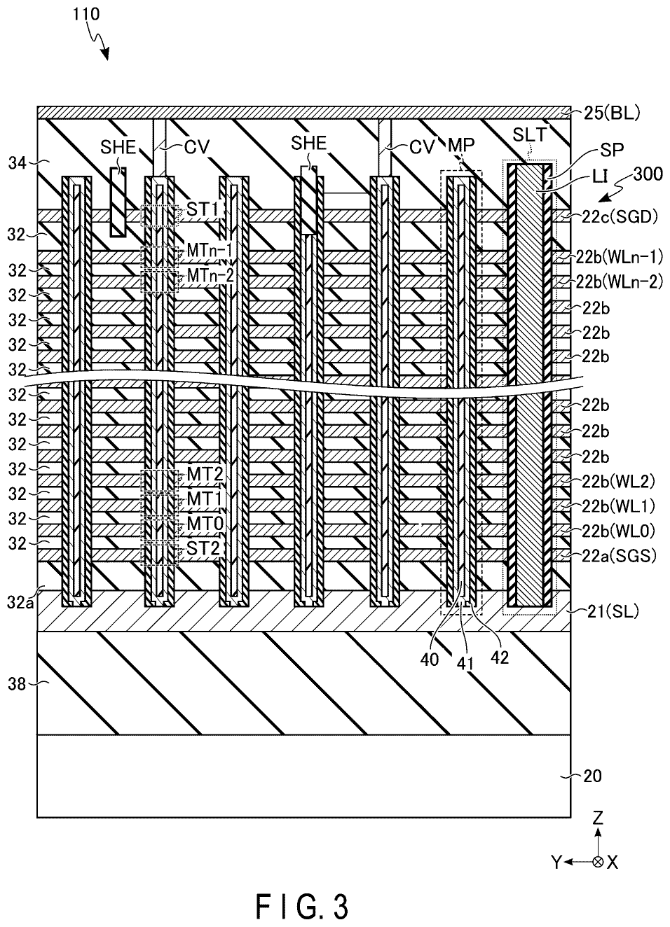

FIG. 3 is a cross-sectional view illustrating a structure example of the memory cell array of the memory device 1 of the present embodiment.

As illustrated in FIG. 3, the memory cell array 110 further includes a substrate 20, conductive layers 21, 22 (22a, 22b, and 22c), and 25, and insulating layers 32a, 32, 34, and 38. The memory cell array 110 has a structure (stacked interconnect) 300 in which a plurality of conductive layers 22 are stacked in the Z direction.

The insulating layer 38 is provided on an upper surface of the substrate 20. The substrate 20 is a semiconductor substrate or an insulator (for example, resin).

The conductive layer 21 is provided on an upper surface of the insulating layer 38. The conductive layer 21 is, for example, a plate-shaped layer extending along the X-Y plane. The conductive layer 21 is used as the source line SL. The conductive layer 21 includes, for example, phosphorus-doped silicon.

The insulating layer 32a is provided on an upper surface of the conductive layer 21. The conductive layer 22a is provided on an upper surface of the insulating layer 32a. The conductive layer 22a is, for example, a plate-shaped layer extending along the X-Y plane. The conductive layer 22a is used as the source-side select gate line SGS. The conductive layer 22a includes (contains), for example, tungsten.

On an upper surface of the conductive layer 22a, the insulating layer 32 and the conductive layer 22b are alternately stacked in the Z direction. The conductive layer 22b is, for example, a plate-shaped layer extending along the X-Y plane. A plurality of stacked conductive layers 22b are used as the word lines WL0, . . . , and WLn−1, respectively, in order from the substrate 20 side. The conductive layer 22b includes, for example, tungsten.

The conductive layer 22c is provided above the uppermost conductive layer 22b via the insulating layer 32. The conductive layer 22c is, for example, a plate-shaped layer extending along the XY plane. The conductive layer 22c is used as the drain-side select gate line SGD. The conductive layer 22c includes, for example, tungsten.

The insulating layer 34 is provided on an upper surface of the conductive layer 22c. The insulating layer 34 may include a plurality of insulating layers. The conductive layer 25 is provided on an upper surface of the insulating layer 34. The conductive layer 25 is, for example, a line-shaped layer extending in the Y direction. The conductive layer 25 is used as the bit line BL. In a region not illustrated, a plurality of conductive layers 25 are arranged along the X direction. The conductive layer 25 includes, for example, copper.

Each memory pillar MP is provided in the stacked interconnect 300 and extends along the Z direction. The memory pillar MP penetrates the insulating layer 32 and the conductive layer 22. A bottom portion of the memory pillar MP is in contact with the conductive layer 21. A portion where the memory pillar MP and the conductive layer 22a intersect each other functions as the select transistor ST2. A portion where the memory pillar MP and a conductive layer 22b intersect each other functions as a memory cell transistor MT. A portion where the memory pillar MP and the conductive layer 22c intersect each other functions as the select transistor ST1.

Each memory pillar MP includes, for example, a core member 40, a semiconductor layer 41, and a stacked film 42. The core member 40 is provided to extend along the Z direction. For example, an upper end of the core member 40 is included in a layer above the conductive layer 22c. A lower end of the core member 40 reaches the conductive layer 21. The semiconductor layer 41 covers the periphery of the core member 40. In a lower portion of the memory pillar MP, a part of the semiconductor layer 41 is in contact with the conductive layer 21. The stacked film 42 covers a side surface and a bottom surface of the semiconductor layer 41 except a portion where the semiconductor layer 41 and the conductive layer 21 are in contact with each other. The core member 40 includes, for example, an insulator such as silicon oxide. The semiconductor layer 41 includes, for example, silicon.

A columnar contact CV is provided on an upper surface of the semiconductor layer 41 in the memory pillar MP. In the illustrated region, two contacts CV respectively corresponding to the two memory pillars MP, respectively, among the six memory pillars MP are illustrated. The contact CV is connected to the memory pillar MP which does not overlap a slit SHE and to which no contact CV is connected, in a region not illustrated (for example, a region in a depth direction or a front direction of the paper surface).

A conductive layer 25 (a bit line BL) is in contact with an upper surface of the contact CV. In each of spaces divided by a slit SLT and the slit SHE, a contact CV is connected to a conductive layer 25. Each conductive layer 25 is electrically connected to the memory pillar MP provided between the adjacent slits SLT and SHE and the memory pillar MP provided between the two adjacent slits SHE.

The slit SLT has, for example, a portion provided along the X-Z plane, and divides the conductive layers 22. A contact LI in the slit SLT is provided along the slit SLT. A part of an upper end of the contact LI is in contact with the insulating layer 34. A lower end of the contact LI is in contact with the conductive layer 21. The contact LI is, for example, a conductor used as a part of the source line SL. The spacer SP is provided at least between the contact LI and the conductive layer 22. The contact LI is separated and insulated from the conductive layer 22 by the spacer SP. The spacer SP is an insulating layer. The slit SLT may be filled with an insulator.

The slit SHE has, for example, a portion provided along the X-Z plane, and divides at least the conductive layers 22c. An upper end of the slit SHE is in contact with the insulating layer 34. A lower end of the slit SHE is in contact with the insulating layer 32 between the uppermost conductive layer 22b and the conductive layer 22c. The slit SHE includes, for example, an insulator such as silicon oxide.

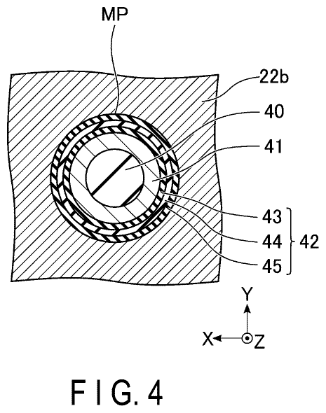

FIG. 4 is a cross-sectional view illustrating an example of a cross-sectional structure of the memory pillar MP in the memory device 1 of the present embodiment. FIG. 4 illustrates a cross-sectional structure of the memory pillar MP in a layer parallel to the surface of the substrate 20 and including the conductive layer 22b.

As illustrated in FIG. 4, the stacked film 42 includes, for example, a tunnel insulating film 43, a charge trap film 44, and a block insulating film 45.

In a cross section including the conductive layer 22b, the core member 40 is provided at a central portion of the memory pillar MP. The semiconductor layer 41 surrounds a side surface of the core member 40. The tunnel insulating film 43 surrounds the side surface of the semiconductor layer 41. The charge trap film 44 surrounds a side surface of the tunnel insulating film 43. The block insulating film 45 surrounds a side surface of the charge trap film 44. The conductive layer 22b surrounds a side surface of the block insulating film 45. The tunnel insulating film 43 includes, for example, silicon oxide. The charge trap film 44 includes, for example, silicon nitride. The block insulating film 45 includes, for example, silicon oxide or aluminum oxide.

In each of the memory pillars MP described above, the semiconductor layer 41 is used as a channel region (current path) of the memory cell transistors MT0, . . . , and MTn−1 and the select transistors ST1 and ST2. The charge trap film 44 is used as a charge storage layer of the memory cell transistor MT. The memory device 1 can cause a current to flow between the bit line BL and the contact LI (source line SL) through the memory pillar MP by turning on the memory cell transistors MT0, . . . , and MTn−1 and the select transistors ST1 and ST2.

A memory cell MT can store data of 1 bit or more by associating a threshold voltage of the memory cell MT with the data to be stored. The memory cell MT that stores 1-bit data is referred to as SLC. The memory cell MT that stores 2-bit data is referred to as MLC. The memory cell MT that stores 3-bit data is referred to as TLC. The memory cell MT that stores 4-bit data is referred to as QLC. The memory cell MT that stores 5-bit data is referred to as PLC.

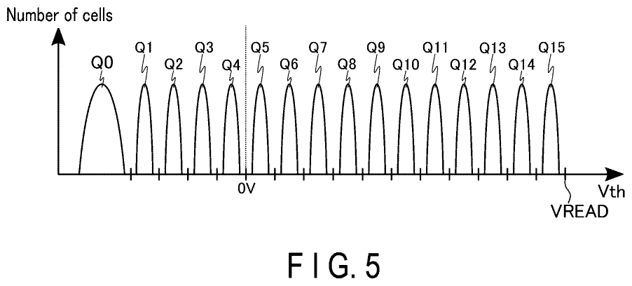

FIG. 5 is a diagram illustrating an example of a relationship between the threshold voltage of the memory cell MT and data. The horizontal axis of a graph of FIG. 5 indicates the threshold voltage (voltage value) Vth of the memory cell MT. The vertical axis of the graph of FIG. 5 indicates the number of memory cells. FIG. 5 illustrates an example in which the memory cell is QLC.

As illustrated in FIG. 5, when a memory cell MT stores 4-bit data, a threshold voltage distribution of the memory cell MT has 16 types of states. In the present embodiment, the 16 types of states are referred to as “Q0”, “Q1”, “Q2”, “Q3”, “Q4”, “Q5”, “Q6”, “Q7”, “Q8”, “Q9”, “Q10”, “Q11”, “Q12”, “Q13”, “Q14”, and “Q15” states in order from the lowest threshold voltage Vth. Different 4-bit data is allocated to each of the “Q0”, “Q1”, . . . , and “Q15” states.

When the threshold voltage of the memory cell MT is higher than the applied read voltage, the memory cell MT is turned off. When the threshold voltage of the memory cell MT is equal to or lower than the applied read voltage, the memory cell MT is turned on. As described above, the magnitude relationship of the threshold voltage of the memory cell with respect to the applied read voltage can be determined by turning on or off the memory cell MT according to the application of the read voltage.

The non-selected voltage VREAD is a voltage to be applied to the non-selected word line WL during the read operation. The voltage value of the non-selected voltage VRED is higher than the threshold voltage of the uppermost state Q15. Therefore, when the non-selected voltage VREAD is applied to a gate of the memory cell MT, the memory cell MT is turned on regardless of the stored data.

Among a plurality of threshold voltage distributions, the threshold voltage distributions of the lower five states Q0, Q1, Q2, Q3, and Q4 have a voltage value (negative voltage value) of 0 V or less. The threshold voltage distributions of the states Q5, Q6, . . . , and Q15 have a voltage value (positive voltage value) higher than 0 V. The number of states having negative threshold voltages is arbitrary.

As described above, the memory cell MT in which data is programmed may have a negative threshold voltage according to the data allocation to the threshold voltage of the memory cell MT.

(a-2) Voltage Generator

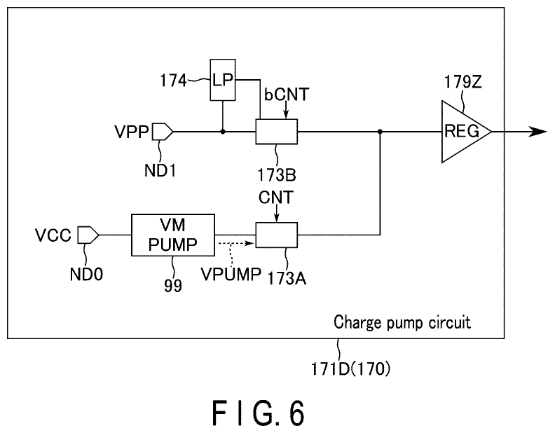

A configuration example of the voltage generator 170 in the memory device 1 of the present embodiment will be described with reference to FIGS. 6, 7, and 8.

FIG. 6 is a circuit diagram illustrating a circuit configuration of the voltage generator 170 of the memory device 1 of the present embodiment. FIG. 6 illustrates a circuit configuration of the voltage generator 170 in a certain voltage system including the charge pump circuit 171.

As illustrated in FIG. 6, the charge pump circuit 171 (171D) is provided in a certain voltage system in the voltage generator 170. For example, the charge pump circuit 171D of FIG. 6 generates an intermediate level voltage (hereinafter, referred to as intermediate voltage) VM among various operating voltages used for the operation of the memory device 1, such as the non-selected voltage VREAD or the non-selected voltage VPASS.

The charge pump circuit 171D includes a charge pump (pump group) 99, switch circuits 173A and 173B, a local pump 174, and a regulator 179Z.

An input node of the charge pump 99 is connected to the voltage node (also referred to as input node or power supply node) ND0 of the voltage generator 170. The external voltage VCC is applied to the voltage node ND0. An output node of the charge pump 99 is connected to an input node of the regulator 179Z via the switch circuit 173A. The charge pump 99 generates a charge pump voltage VPUMP by boosting the external voltage VCC. The charge pump 99 outputs the generated charge pump voltage VPUMP.

The switch circuit 173A controls an electrical connection between the charge pump 99 and the regulator 179Z. The switch circuit 173A is turned on and off according to a control signal CNT.

The external voltage VPP is applied to the voltage node ND1 of the voltage generator 170. The voltage node ND1 is connected to an input node of the regulator 179Z via a switch circuit 173B.

The switch circuit 173B controls an electrical connection between the voltage node ND1 and the regulator 179Z. The switch circuit 173B is turned on and off according to a control signal bCNT. For example, the control signal bCNT has a complementary relationship with the control signal CNT. Signal levels of the control signals CNT and bCNT are controlled by the sequencer 190.

One node of the local pump 174 is connected to a control node of the switch circuit 173B. The other node of the local pump 174 is connected to the voltage node ND1. The local pump 174 boosts the external voltage VPP. The local pump 174 supplies the boosted voltage to the switch circuit 173B. The switch circuit 173B is driven by the boosted voltage. As a result, the switch circuit 173B can transfer the external voltage VPP.

The input node of the regulator 179Z is connected to the switch circuit 173A and the switch circuit 173B. The regulator 179 receives one of the external voltage VPP and the charge pump voltage VPUMP according to the states of the switch circuits 173A and 173B.

The regulator 179Z adjusts the magnitude of the voltage supplied to the input node of the regulator 179Z. As a result, the regulator 179Z outputs an operating voltage having the desired voltage value to the row control circuit 140 or the sense amplifier circuit 150.

The sequencer 190 controls the signal levels of the control signals CNT and bCNT according to an operation mode (hereinafter, also referred to as voltage generation mode) set in the voltage generator 170. As a result, the voltage to be supplied to the regulator 179Z is selected from the external voltage VPP and the charge pump voltage VPUMP according to the voltage generation mode of the charge pump circuit 171D.

Depending on the voltage to be output from the charge pump circuit 171D (voltage generator 170) to another circuit, the voltage generated by the charge pump 99 may be directly output to the outside of the charge pump circuit 171D without passing through the regulator 179Z.

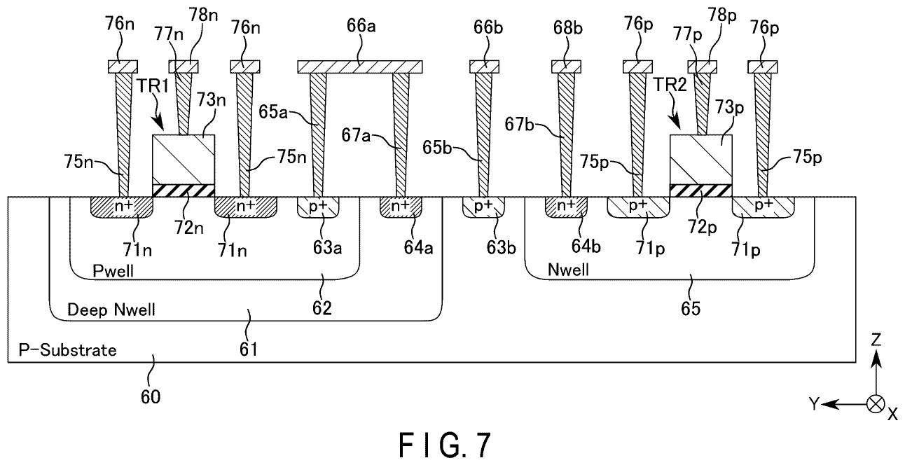

FIG. 7 is a cross-sectional view illustrating a structure example of elements constituting the voltage generator 170 in the memory device 1 of the present embodiment. In FIG. 7, an interlayer insulating film covering elements of the voltage generator 170 is not illustrated.

In the memory device 1 of the present embodiment, the voltage generator 170 includes a transistor TR (TR1 and TR2) having a triple well structure. The transistor TR is a low breakdown voltage transistor LV. The threshold voltage of the transistor TR (low breakdown voltage transistor LV) is lower than the threshold voltage of the transfer gate HV. For example, the threshold voltage (gate-source voltage) of the transistor TR is about 0.5 V to 1.0 V, and the threshold voltage of the transfer gate HV is about 1 V to 2 V.

The transistors TR1 and TR2 are provided on a P-type semiconductor substrate 60. For example, the semiconductor substrate 60 is provided below the memory cell array 110 in the Z direction.

An N-type well 61 is provided in the semiconductor substrate 60. A P-type well 62 is provided in the N-type well 61. The N-type well 61 surrounds the P-type well 62. A bottom portion of the N-type well 61 is disposed at a position deeper than the bottom portion of the P-type well 62 in the Z direction.

The transistor TR1 is disposed on the P-type well 62. The transistor TR1 is an N-type field effect transistor. The transistor TR1 includes two source/drain layers 71n, a gate insulating film 72n, and a gate electrode 73n.

The N-type source/drain layer (diffusion layer or impurity region) 71n is provided in the P-type well 62. The gate insulating film 72n is provided on the P-type well 62. The gate insulating film 72n is disposed on the channel region between the two source/drain layers 71n. The gate electrode 73n is provided on the gate insulating film 72n. The gate electrode 73n faces the channel region via the gate insulating film 72n.

A contact plug 75n is provided on the source/drain layer 71n. An interconnect 76n is provided on the contact plug 75n. The interconnect 76n is connected to the source/drain layer 71n via the contact plug 75n.

The contact plug 77n is provided on the gate electrode 73n. An interconnect 78n is provided on the contact plug 77n. The interconnect 78n is connected to the gate electrode 73n via the contact plug 77n. A gate voltage is applied to the gate electrode 73n via the interconnect 78n and the contact plug 77n.

An N-type well 65 is provided in the semiconductor substrate 60. The N-type well 65 is adjacent to the N-type well 61 in the Y direction.

The transistor TR2 is disposed on the N-type well 65. The transistor TR2 is a P-type field effect transistor. The transistor TR2 includes two source/drain layers 71p, a gate insulating film 72p, and a gate electrode 73p.

For example, the N-type well 65 is formed in a separate step from the N-type well 61. Therefore, the depth of the N-type well 65 (position of a bottom portion of the well 65 in the Z direction) is different from the depth of the N-type well 61. An impurity concentration of the N-type well 65 (concentration of an N-type dopant) is different from an impurity concentration of the N-type well 61. The impurity concentration of the N-type well 61 is lower than the impurity concentration of the N-type well 65. However, the N-type well 65 may be formed in the same step as the N-type well 61, and the depth of the N-type well 65 may be the same as the depth of the N-type well 61.

The P-type source/drain layer (diffusion layer or impurity region) 71p is provided in the N-type well 65. The gate insulating film 72p is provided on the N-type well 65. The gate insulating film 72p is disposed on the channel region between the two source/drain layers 71p. The gate electrode 73p is provided on the gate insulating film 72p. The gate electrode 73p faces the channel region via the gate insulating film 72p.

A contact plug 75p is provided on the source/drain layer 71p. An interconnect 76p is provided on the contact plug 75p. The interconnect 76p is connected to the source/drain layer 71p via the contact plug 75p.

The contact plug 77p is provided on the gate electrode 73p. An interconnect 78p is provided on the contact plug 77p. The interconnect 78p is connected to the gate electrode 73p via the contact plug 77p. A gate voltage is applied to the gate electrode 73p via the interconnect 78p and the contact plug 77p.

A P-type diffusion layer 63a is provided in the P-type well 62. A contact plug 65a is provided on the diffusion layer 63a. An interconnect 66a is provided on the contact plug 65a. The interconnect 66a is connected to the diffusion layer 63a via the contact plug 65a.

An N-type diffusion layer 64a is provided in the N-type well 61. A contact plug 67a is provided on the diffusion layer 64a. The contact plug 67a is connected to the wiring 66a. The interconnect 66a is connected to the diffusion layer 64a via the contact plug 67a. The diffusion layer 64a is connected to the diffusion layer 63a via the contact plugs 65a and 67a and the interconnect 66a. A certain voltage is applied to the N-type well 61 and the P-type well 62 via the interconnect 66a, the contact plugs 65a and 67a, and the diffusion layers 63a and 64a.

An N-type diffusion layer 64b is provided in the N-type well 65. A contact plug 67b is provided on the diffusion layer 64b. An interconnect 68b is provided on the contact plug 67b. The interconnect 68b is connected to the diffusion layer 64b via the contact plug 67b. A certain voltage is applied to the N-type well 65 via the interconnect 68b, the contact plug 67b, and the diffusion layer 64b.

A P-type diffusion layer 63b is provided in the semiconductor substrate 60 between the N-type well 61 and the N-type well 65. A contact plug 65b is provided on the diffusion layer 63b. An interconnect 66b is provided on the contact plug 65b. The interconnect 66b is connected to the diffusion layer 63b via a contact plug 65b. A certain voltage is applied to the semiconductor substrate 60 via the interconnect 66b, the contact plug 65b, and the diffusion layer 63b. Application of a voltage lower than those of the N-type well 61 and the N-type well 65 to the diffusion layer 63b and the semiconductor substrate 60 avoids application of a forward bias to a PN junction. The diffusion layer 63b suppresses latch-up and functions as a guard ring.

In the semiconductor substrate 60, a PNP junction bipolar transistor is parasitically formed by the P-type semiconductor substrate 60, the N-type well 65, and the P-type diffusion layer (source/drain layer) 71p. In the semiconductor substrate, an NPN junction bipolar transistor is parasitically formed by the N-type well 61, the P-type semiconductor substrate 60, and the N-type well 65. However, these parasitic bipolars do not adversely affect the operation of the transistor TR by applying a voltage lower than those of the N-type well 61 and the N-type well 65 to the diffusion layer 63b.

In the voltage generator 170, the transistor TR having a triple well structure is used in, for example, a charge transfer switch in the charge pump circuit 171. The voltage generator 170 can use a low breakdown voltage transistor for transfer of charge (voltage) by the transistor TR having a triple well structure. As a result, the voltage generator 170 can realize high-speed charge transfer and circuit size reduction.

In addition, in the transistor TR having a triple well structure, by controlling the voltage of the substrate 60 and the voltages of the wells 61, 62, and 65, an increase in threshold voltages of the N-type and P-type transistors TR1 and TR2 due to a back bias effect can be avoided.

In the memory device 1 of the present embodiment, the charge pump circuit 171 of the voltage generator 170 generates and outputs various operating voltages used in the operation of the memory device 1 according to a plurality of operation modes (voltage generation modes).

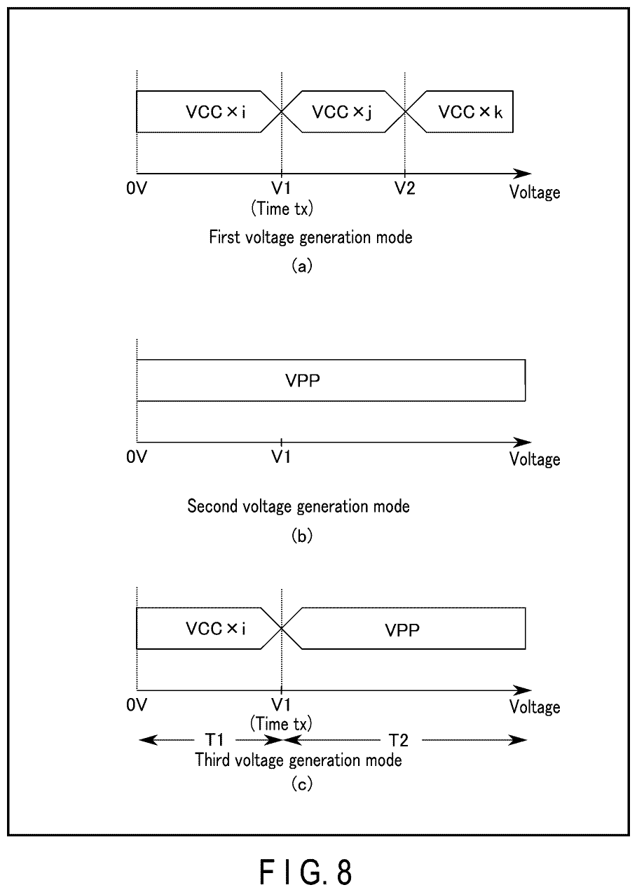

FIG. 8 is a schematic diagram for explaining the voltage generation modes of the charge pump circuit 171 in the voltage generator 170 of the memory device 1 of the present embodiment.

As illustrated in (a), (b), and (c) of FIG. 8, in the voltage generator 170 of the memory device 1 of the present embodiment, the charge pump circuit 171 (171D) generates the operating voltage by any one of the three voltage generation modes.

As illustrated in (a) of FIG. 8, in a first voltage generation mode, the charge pump circuit 171 boosts the external voltage VCC across a plurality of pump stages by the charge pump 99 as a voltage generation source to generate an operating voltage having a predetermined voltage value.

For example, in the first voltage generation mode, the voltage generator 170 boosts the external voltage VCC by i (i is a natural number of 1 or more) pump stages of the charge pump 99. Accordingly, in a certain operation period (certain time tx), the voltage generator 170 generates a voltage (voltage value) V1.

After the generated voltage reaches the voltage V1, the charge pump circuit 171 increases the number of pump stages and boosts the external voltage VCC by j (j is a natural number greater than i) pump stages of the charge pump 99. As a result, a voltage (voltage value) V2 higher than the voltage V1 is generated.

The charge pump circuit 171 increases the number of pump stages used by the charge pump 99 from j to k (k is a natural number greater than j), and boosts the external voltage VCC to a voltage equal to or higher than the voltage V2 by k pump stages of the charge pump 99.

As described above, the charge pump circuit 171 in the first voltage generation mode gradually boosts the external voltage VCC to generate a predetermined operating voltage.

As illustrated in (b) of FIG. 8, in a second voltage generation mode, the charge pump circuit 171 generates a predetermined operating voltage using the external voltage VPP higher than the external voltage VCC as the voltage generation source. For example, the charge pump circuit 171 steps down the external voltage VPP having a constant voltage value by the regulator 179Z to generate an operating voltage having a predetermined voltage value.

As described above, the charge pump circuit 171 in the second voltage generation mode adjusts the external voltage VPP to generate a predetermined operating voltage.

As illustrated in (c) of FIG. 8, in a third voltage generation mode, the charge pump circuit 171 generates a voltage having a predetermined voltage value using the voltage boosted by the charge pump 99 and the external voltage VPP. For example, in the third voltage generation mode, the charge pump circuit 171 boosts the external voltage VCC by i pump stages in the charge pump 99 in a period T1 from the start of voltage generation (time 0) to the time tx, and generates the voltage V1. The voltage value of the voltage V1 is lower than the voltage value of the external voltage VPP.

In each voltage generation mode, when the charge pump voltage VPUMP is selected, the voltage used as the power supply is set to the external voltage VCC, and the external voltage VCC is boosted. When a voltage higher than the external voltage VPP is generated at a time of selecting the external voltage VPP, the external voltage VPP is set to a voltage used as the power supply, and the external voltage VPP is boosted by the charge pump 99.

In a period T2 after reaching the voltage V1, the charge pump circuit 171 in the third voltage generation mode changes the external voltage for generating the voltage from the external voltage VCC to the external voltage VPP. As a result, in the charge pump circuit 171 in the third voltage generation mode, the voltage generation source is switched from the charge pump 99 to the external voltage VPP. For example, when the voltage value of the generated voltage (as an example, the voltage VREAD or the voltage VPASS) is about 6 V, the voltage value of the voltage is boosted by the charge pump 99 from about 4 V to about 5 V, and is generated by stepping down the external voltage VPP after 5 V. In this case, the period T1 may be longer than the period T2. However, the period T2 can be longer than the period T1 depending on the magnitude of the generated voltage.

As a result, the charge pump circuit 171 in the third voltage generation mode generates an operating voltage having a predetermined voltage value using the external voltage VPP after the time tx when the generated voltage reaches the voltage V1.

As described above, the memory device 1 of the present embodiment selects any one of the three voltage generation modes of the charge pump circuit of the voltage generator 170. The memory device 1 of the present embodiment generates a voltage for the operation of the memory device 1 by the charge pump circuit 171 operating based on the selected voltage generation mode.

### (b) Operation Example

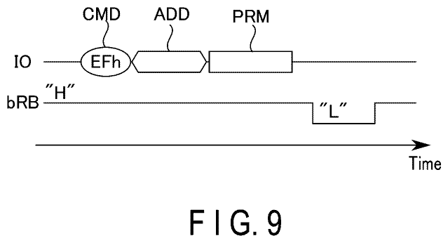

An operation example of the memory device 1 of this embodiment will be described with reference to FIGS. 9, 10, 11, and 12. The operation example of the memory device 1 of the present embodiment corresponds to a method of controlling the memory device 1.

(b-1) Setting of Voltage Generation Mode

Setting of the voltage generation mode of the charge pump circuit 171 of the voltage generator 170 in the memory device 1 of the present embodiment will be described with reference to FIG. 9.

FIG. 9 is a schematic diagram for explaining processing for setting and changing the voltage generation mode in the memory device 1 of the present embodiment.

As illustrated in FIG. 9, in the present embodiment, the setting and change of the voltage generation mode are executed by the command CMD based on the interface (here, NAND interface) of the memory device 1.

When the voltage generation mode is set or changed, the memory controller 5 sends a command (SetFeature command) CMD of “EFh” to the memory device 1. Following the command CMD, the memory controller 5 sends the address ADD of a storage area that stores the parameter PRM to the memory device 1. Thereafter, the memory controller 5 sends the parameter (data) PRM indicating the voltage generation mode set in the memory device 1 to the memory device 1.

The memory device 1 sequentially receives the command CMD, the address ADD, and the parameter PRM.

The memory device 1 changes the signal level of the ready/busy signal RBn from “H” level to “L” level. The state of the memory device 1 is set to a busy state.

The memory device 1 stores the parameter PRM in the storage area indicated by the address ADD based on the command CMD during a busy state period. During operation of the memory system SYS, the parameter PRM is temporarily stored in the register 191 of the sequencer 190.

As a result, the voltage generation mode to be used is set in the memory device 1.

As described above, the memory device 1 of the present embodiment sets the voltage generation mode of the voltage generator 170.

The voltage generation mode indicated by the parameter PRM may be two modes, i.e., the first voltage generation mode and the third voltage generation mode.

(b-2) Operation of Voltage Generator in Each Mode

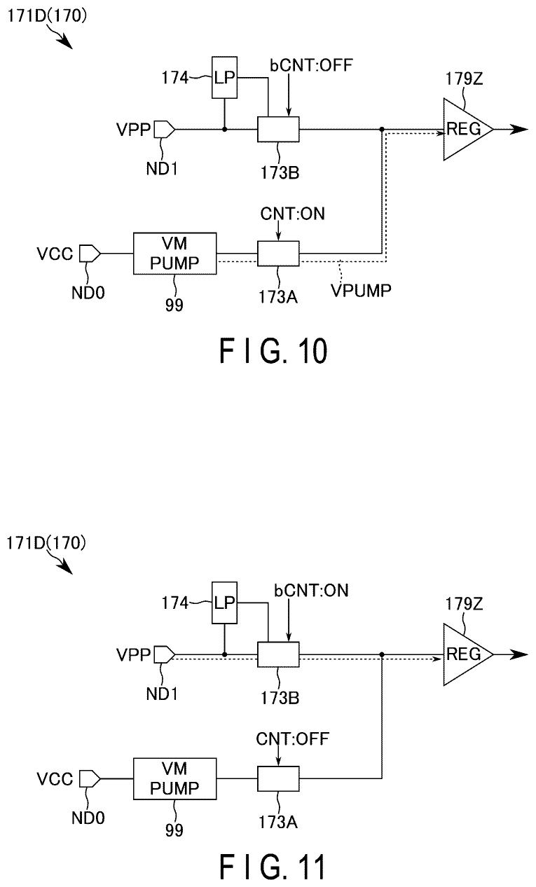

The operation of the charge pump circuit 171 (171D) of the voltage generator 170 in the memory device 1 of this embodiment will be described with reference to FIGS. 10, 11, and 12.

(b-2-1) First Voltage Generation Mode

FIG. 10 is a schematic diagram illustrating an operation state of the charge pump circuit 171D in the first voltage generation mode in the voltage generator 170 of the memory device 1 of the present embodiment.

As illustrated in FIG. 10, in the first voltage generation mode set according to the parameter PRM, the switch circuit 173A is turned on and the switch circuit 173B is turned off based on the control signals CNT and bCNT.

The voltage node ND1 of the external voltage VPP is electrically separated from the regulator 179Z by the switch circuit 173B in an OFF state. The charge pump 99 is electrically connected to the regulator 179Z via the switch circuit 173A in an ON state.

The charge pump 99 executes a boosting operation of the external voltage VCC. For example, the charge pump (VMPUMP) 99 generates the non-selected voltage VREAD during the read operation or the non-selected voltage VPASS during the program operation.

As illustrated in (a) of FIG. 8, the charge pump 99 boosts the external voltage VCC by the i pump stages in a voltage range (low voltage range) from 0 V to a certain voltage V1. The charge pump 99 boosts the voltage by j pump stages in a voltage range from the voltage V1 to the voltage V2. The charge pump 99 boosts the voltage by the k pump stages in a voltage range higher than the voltage V2.

By boosting the external voltage VCC by such a plurality of pump stages, the charge pump 99 generates the charge pump voltage VPUMP having a desired voltage value. The charge pump 99 supplies the generated charge pump voltage VPUMP to the regulator 179Z via the switch circuit 173A in the ON state.

The regulator 179Z adjusts the supplied charge pump voltage VPUMP. The regulator 179Z outputs the adjusted voltage (or unadjusted voltage) to the row control circuit 140. In a case where the voltage output from the regulator 179Z is supplied to the sense amplifier circuit 150, the sense amplifier circuit 150 controls the voltage of the bit line BL using the supplied voltage.

As a result, various operating voltages for the operation to be executed are supplied to the word line WL and the bit line BL in the memory cell array 110.

### (B-2-2) Second Voltage Generation Mode

FIG. 11 is a schematic diagram illustrating an operation state of the charge pump circuit 171D in the second voltage generation mode in the voltage generator 170 of the memory device 1 of the present embodiment.

As illustrated in FIG. 11, in the second voltage generation mode set according to the parameter PRM, the switch circuit 173A is turned off and the switch circuit 173B is turned on based on the control signals CNT and bCNT.

The voltage node ND1 to which the external voltage VPP is applied is electrically connected to the regulator 179Z via the switch circuit 173B in the ON state. The charge pump 99 is electrically separated from the regulator 179Z by the switch circuit 173A in the OFF state.

As illustrated in (b) of FIG. 8, the external voltage VPP is supplied to the regulator 179Z via the switch circuit 173B in the ON state. A voltage path (interconnect) between the voltage node ND1 and the regulator 179Z is gradually charged according to the output (gate voltage of the switch circuit 173B) of the local pump 174 by negative feedback control of the monitoring result of the voltage to be supplied to the regulator 179Z. At this time, the current Ipp is generated by charging the interconnect by the voltage VPP.

The regulator 179Z adjusts the voltage value of the supplied external voltage VPP. For example, the regulator 179Z steps down the voltage of the supplied external voltage VPP. The regulator 179Z outputs the adjusted voltage (or unadjusted voltage) to the row control circuit 140 or the sense amplifier circuit 150.

As a result, various operating voltages for the operation to be executed are supplied to the word line WL and the bit line BL in the memory cell array 110.

(b-2-3) Third Voltage Generation Mode

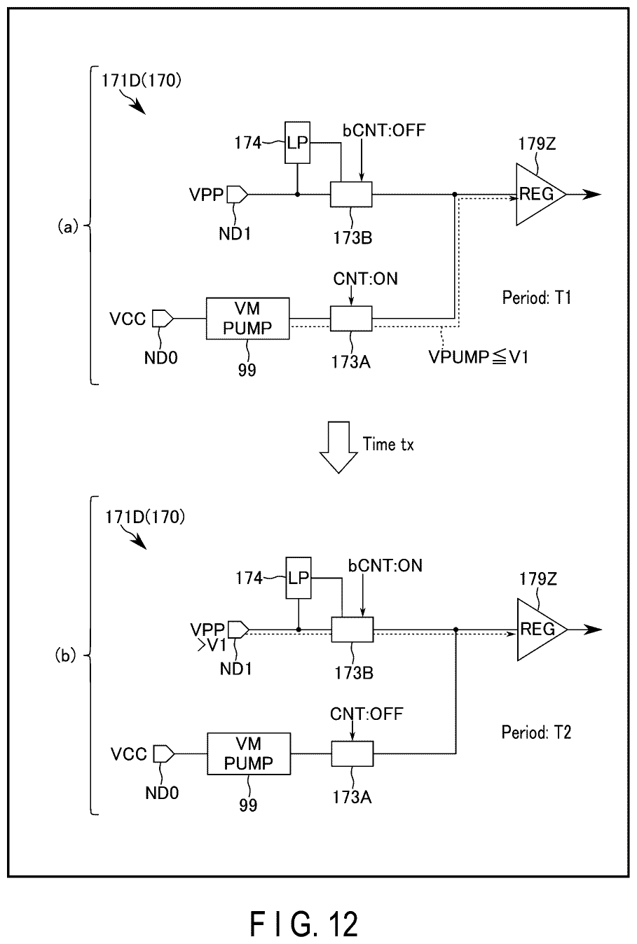

FIG. 12 is a schematic diagram illustrating an operation state of the charge pump circuit 171D in the third voltage generation mode in the voltage generator 170 of the memory device 1 of the present embodiment.

(a) of FIG. 12 illustrates a state in a period (first period) in which the voltage VPUMP from the charge pump 99 is supplied to the regulator 179Z in the third voltage generation mode. (b) of FIG. 12 illustrates a state in a period (second period) in which the external voltage VPP is supplied to the regulator 1792 in the third voltage generation mode.

As illustrated in (a) of FIG. 12, the charge pump circuit 171D starts the operation in the third voltage generation mode set according to the parameter PRM. In the first period T1 (in other words, the voltage value range in which the voltage supply source is switched) set in advance in the third voltage generation mode, the switch circuit 173A is turned on and the switch circuit 173B is turned off based on the control signals CNT and bCNT.

The voltage node ND1 of the external voltage VPP is electrically separated from the regulator 179Z by the switch circuit 173B in an OFF state. The charge pump 99 is electrically connected to the regulator 179 via the switch circuit 173A in an ON state.

The charge pump 99 executes a boosting operation of the external voltage VCC.

The charge pump 99 boosts the external voltage VCC by the i pump stages in a voltage range (low voltage range) from 0 V to a certain voltage V1. The charge pump 99 supplies the charge pump voltage VPUMP generated by boosting to the regulator 179Z.

The regulator 179Z outputs the adjusted charge pump voltage (or unadjusted charge pump voltage) VPUMP.

By boosting the voltage, the magnitude of the charge pump voltage VPUMP reaches the voltage V1.

During the operation in the third voltage generation mode, at the time tx when the magnitude of the charge pump voltage VPUMP reaches the voltage V1, the charge pump circuit 171D switches the voltage path to the regulator 179Z under the control of the sequencer 190.

At the time tx, the sequencer 190 changes the signal levels of the control signals CNT and bCNT.

As illustrated in (b) of FIG. 12, in the second period T2 of the set third voltage generation mode, the switch circuit 173A is turned off and the switch circuit 173B is turned on based on the control signals CNT and bCNT.

The voltage node ND1 to which the external voltage VPP is applied is electrically connected to the regulator 179Z via the switch circuit 173B in the ON state. The charge pump 99 is electrically separated from the regulator 179Z by the switch circuit 173A in the OFF state.

The external voltage VPP is supplied to the regulator 179Z via the switch circuit 173B in the ON state. The voltage value of the external voltage VPP is higher than the voltage value V1 of the charge pump voltage VPUMP at the time tx.

In this manner, the voltage to be supplied to the regulator 179Z changes from the charge pump voltage VPUMP to the external voltage VPP by switching on and off of the two switch circuits 173A and 173B at the time tx.

For example, the time tx at which the charge pump voltage VPUMP (external voltage VCC) is switched to the external voltage VPP is a preset time. As an example, the time tx is set at a time of shipment of the memory device 1. The time tx may be variably set based on the monitoring result of the voltage value of the charge pump voltage VPUMP.

The regulator 179Z adjusts (for example, steps down) the supplied external voltage VPP. The regulator 179Z outputs the adjusted voltage (or unadjusted voltage) to the row control circuit 140 or the sense amplifier circuit 150.

As a result, various operating voltages for the operation to be executed are supplied to the word line WL and the bit line BL in the memory cell array 110.

As described above, in the third voltage generation mode, the charge pump circuit 171D switches the voltage to be supplied to the regulator 179Z from the charge pump voltage VPUMP to the external voltage VPP in the middle of the generation of the voltage, and outputs the generated operating voltage. That is, the charge pump circuit 171D generates a voltage using the charge pump 99 in a low voltage range equal to or lower than the voltage V1, and generates a voltage using the external voltage VPP in a voltage range higher than the voltage V1.

In the above example, a case where the non-selected voltage VREAD during the read operation is generated using the charge pump voltage VPUMP or the external voltage VPP is illustrated. However, in the memory device 1 of the present embodiment, the charge pump circuit 171 can generate the program voltage VPGM, the erase voltage VERA, the read voltage VCGRV, the non-selected voltage VPASS, the verify voltage, or the voltage VX to be supplied to the sense amplifier circuit 150 in the above-described first, second, and third voltage generation modes.

For example, in the erase operation, the third voltage generation mode in which the switching from the charge pump voltage VPUMP to the external voltage VPP is executed is applied to the voltage generation operation (boosting operation) of the erase voltage VERA to be supplied to the bit line BL and the source line SL. For example, during the program operation of the write operation, the third voltage generation mode in which the switching from the charge pump voltage VPUMP to the external voltage VPP is executed is applied to the voltage generation operation of the non-selected voltage VPASS to be supplied to the non-selected word line.

An interconnect capacitance of the bit line BL and an interconnect capacitance of the non-selected word line WL are relatively large, and a rising time of the voltage becomes relatively long. Therefore, there is a room for time for switching from the charge pump voltage VPUMP to the external voltage VPP at a time of executing the erase operation and the program operation. Therefore, the third voltage generation mode may be applied to the erase operation and the write operation.

### (c) Verification

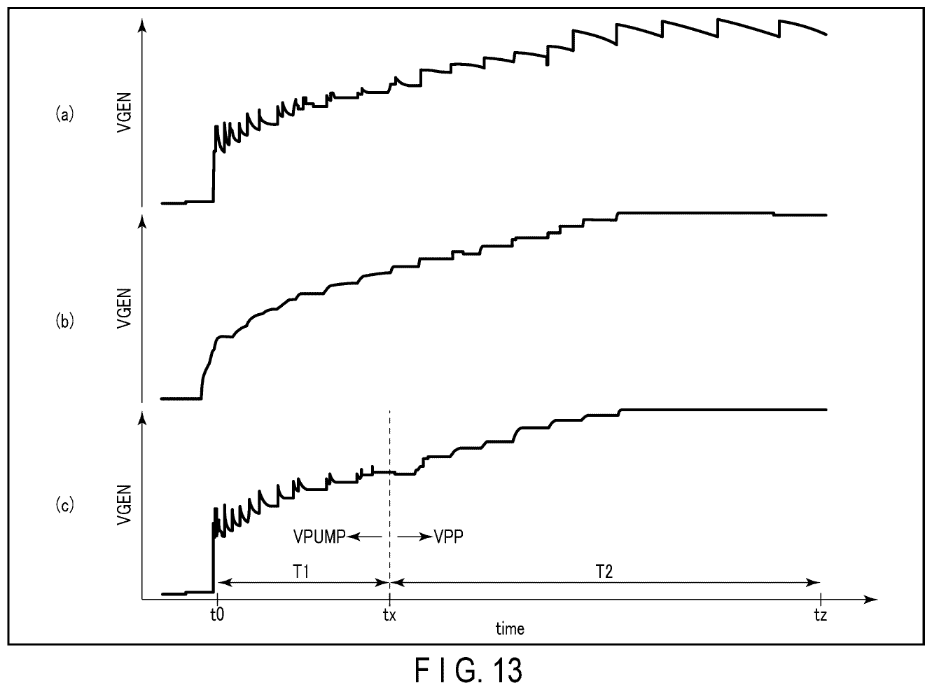

A verification result of the operation of the memory device of the present embodiment will be described with reference to FIGS. 13, 14, 15, and 16.

FIG. 13 illustrates a waveform of a voltage characteristic in each voltage generation mode of the memory device 1 of the present embodiment. In FIG. 13, the horizontal axis of the graph corresponds to the time, and the vertical axis of the graph corresponds to the voltage value of the voltage VGEN output from the voltage generator 170.

(a) of FIG. 13 illustrates the voltage characteristic in the first voltage generation mode. (b) of FIG. 13 illustrates the voltage characteristic in the second voltage generation mode. (c) of FIG. 13 illustrates the voltage characteristic in the third voltage generation mode.

As illustrated in (a) of FIG. 13, in the first voltage generation mode, the charge pump circuit 171 outputs the voltage VPUMP generated by the charge pump 99 as an output voltage VGEN. For example, due to a delay from detection of the voltage value when the desired voltage value is reached to temporary stop of the operation, a ripple occurs in the output voltage VGEN.

As illustrated in (b) of FIG. 13, in the second voltage generation mode, the charge pump circuit 171 outputs the voltage generated from the external voltage VPP as the output voltage VGEN. The voltage value of the output voltage VGEN gradually increases according to charging of the voltage path (interconnect) by the supply of the external voltage VPP.

As illustrated in (c) of FIG. 13, the regulator 179 outputs the charge pump voltage VPUMP as the output voltage VGEN in the period T1 until the time tx. At the time tx, the supply source of the voltage to the regulator 179 is switched from the charge pump 99 to the voltage node ND1 of the external voltage VPP.

In the period T2 from the time tx to a time tz, the regulator 179 outputs a voltage corresponding to the external voltage VPP as the output voltage VGEN.

Even when the switching from the charge pump voltage VPUMP to the external voltage VPP occurs during the output of the voltage VGEN, the regulator 179 can output the voltage VGEN in a state where continuity of the output of the voltage is maintained.

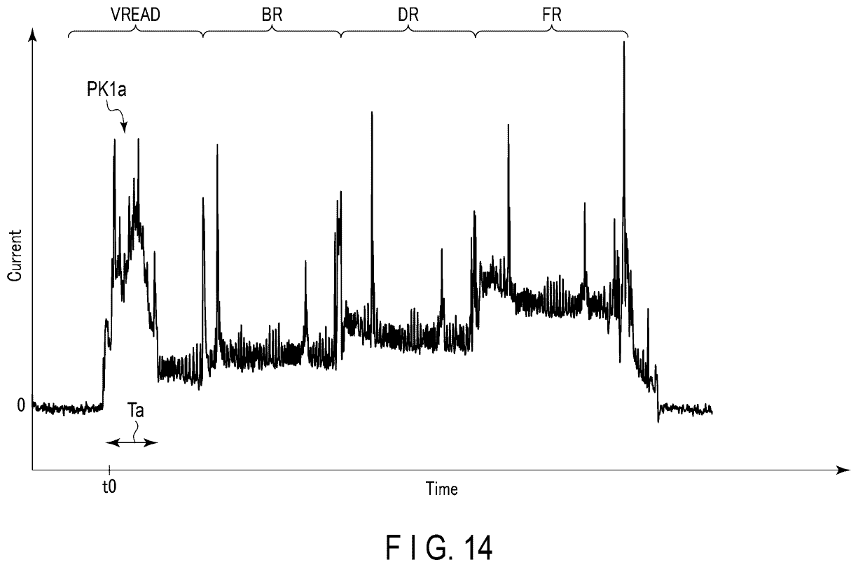

FIGS. 14, 15, and 16 are waveform diagrams illustrating currents generated at a time of voltage generation by the voltage generator 170 in the memory device 1 of the present embodiment.

FIGS. 14, 15, and 16 illustrate waveforms of currents generated during the read operation when a memory cell MT stores 3-bit data (when the memory cell is a TLC). The TLC stores data of an Upper page (Upper bit), a Middle page (Middle), and a Lower page (Lower bit). In the examples of FIGS. 14, 15, and 16, the current Icc due to the read operation of the Middle page data is illustrated.

Regarding the eight types of states (threshold voltage distributions) of the TLC, read of “AR”, “BR”, “CR”, “DR”, “ER”, “FR”, and “GR” in the order from the lower state to the upper state is executed as read of the states. The read of each state classifies a high threshold distribution equal to or higher than a certain level and a threshold distribution lower than the certain level. For example, the read of “CR” classifies a state equal to or higher than the “C” state and a state equal to or lower than the “B” state (a state lower than the “C” state). As a result, a target page data (for example, Middle page data) is read by the read of the states.

FIG. 14 illustrates a current waveform of a current generated from the memory device 1 in the first voltage generation mode. The current waveform indicated by the solid line in FIG. 14 indicates the waveform of the current Icc. The current Icc flows to the voltage node ND0 (or a node of a current sink of a chip). The current Icc is a current of the entire chip of the memory device 1. Therefore, the current Icc includes a current (for example, a cell current during a sense operation) generated by an operation other than the operation using the charge pump circuit 171. Therefore, the current Icc is also generated in the voltage generation mode using the external voltage VPP which will be described later.

As illustrated in FIG. 14, at a time to, the operation of the charge pump circuit 171 is started. In the first voltage generation mode, the charge pump 99 is driven in order to generate a voltage. The current value of the current Icc gradually increases with the lapse of time.

In a period Ta from the time to, a peak PK1a with a large current Icc is generated due to the operation of the charge pump 99.

For example, in the read operation of the Middle page of the TLC, after the application of the non-selected voltage VREAD to the selected word line WL, the read of “BR”, “DR”, and “FR” is sequentially executed.

By the application of the non-selected voltage VREAD in the period Ta, all the memory cells connected to the selected word line WL are turned on. As a result, a current Icc having a large current value (peak PK1a) is generated.

The read of “BR” is executed by application of a read voltage related to the “B” state (hereinafter, also referred to as read voltage VBR). The memory cell having a threshold voltage equal to or lower than the applied read voltage VBR (memory cell of a state lower than the “B” state) is turned on.

After the read of “BR”, the read of “DR” is executed by the application of a read voltage related to the “D” state (hereinafter, also referred to as read voltage VDR). The read voltage VDR related to the “D” state is higher than the read voltage VBR related to the “B” state. The memory cell MT having a threshold voltage equal to or lower than the applied read voltage VDR is turned on.

After the read of “DR”, the read of “FR” is executed by the application of a read voltage related to the “F” state (hereinafter, also referred to as read voltage VFR). The read voltage VFR related to the “F” state is higher than the read voltage VDR related to the “D” state. The memory cell having a threshold voltage equal to or lower than the applied read voltage VFR is turned on.

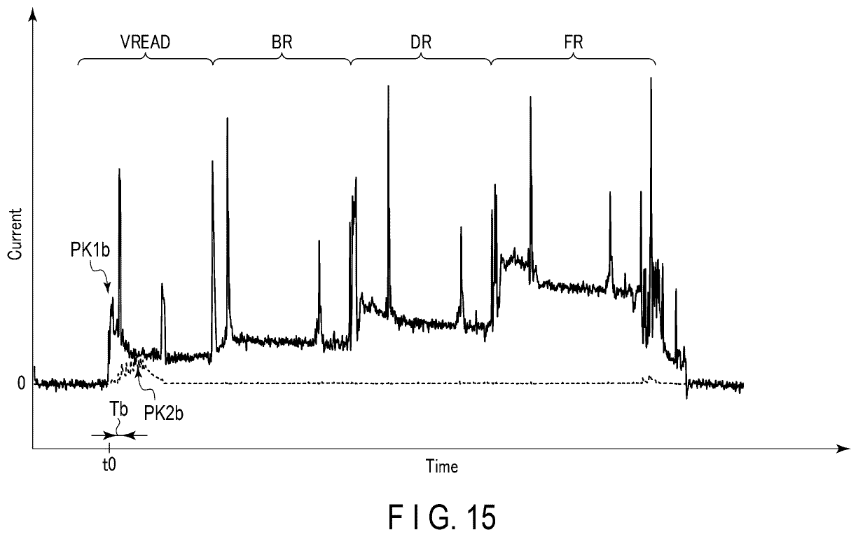

FIG. 15 illustrates current waveforms of currents generated from the memory device 1 in the second voltage generation mode. The current waveform indicated by a solid line in FIG. 15 indicates the waveform of the current Icc. The current waveform indicated by a broken line in FIG. 15 indicates the current Ipp. The current Ipp is a current flowing through the voltage node ND1 to which the external voltage VPP is applied.

As illustrated in FIG. 15, at the time to, the current Icc is generated by the start of the operation of the charge pump circuit 171. In the second voltage generation mode, the current Icc flows according to the supply of the external voltage VPP. In a period Tb from the time to, a current peak PK1b of the current Icc occurs. The period Tb is shorter than the period Ta. For example, the value of the current peak PK1b is smaller than the value of the current peak PK1a.

Due to the supply of the voltage VPP, the current Ipp flows. The peak PK2b of the current Ipp occurs after the peak of the current Icc occurs (after the period Tb elapses).

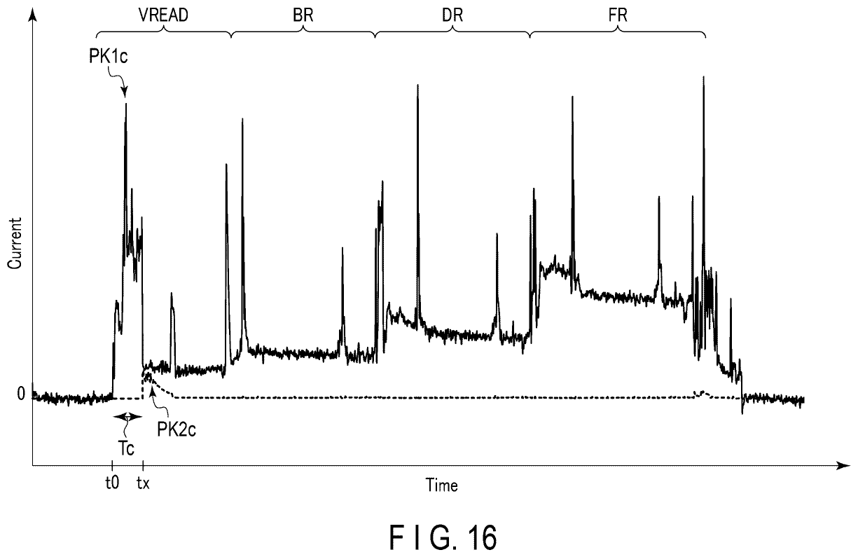

FIG. 16 illustrates current waveforms of currents generated from the memory device 1 in the third voltage generation mode. The current waveform indicated by a solid line in FIG. 16 indicates the waveform of the current Icc. The current waveform indicated by a broken line in FIG. 16 indicates the current Ipp.

As illustrated in FIG. 16, at the start of the operation of the charge pump circuit 171 in the third voltage generation mode, a current peak PKlc of the current Icc occurs in a period Tc due to the operation of the charge pump 99. The period Tc is shorter than the period Ta and longer than the period Tb, for example.

At the time tx, the voltage generation source in the charge pump circuit 171 is switched from the charge pump 99 to the external voltage VPP.

At the time tx, the current peak PKIc of the current Icc converges (decreases) by cutoff of the voltage supply from the charge pump 99 (stop of the charge pump 99). At this time tx, a current peak PK2c of the current Ipp occurs due to the supply of the external voltage VPP. A timing of occurrence of the current peak PK2c of the current Ipp in the third voltage generation mode is later than a timing of occurrence of the current peak PK2b of the current Ipp in the second voltage generation mode. For example, the timing of occurrence of the current peak PK2c of the current Ipp in the third voltage generation mode is a time (period) after the time tx.

As described above, the waveforms of the currents Icc and Ipp occurring at the start of voltage generation are different according to the voltage generation mode of the charge pump circuit 171 in the voltage generator 170.

### (d) Summary

A general memory device selects one of the operation mode in which the operating voltage is produced by boosting the external voltage VCC and the operation mode in which the operating voltage is produced by adjusting (for example, stepping down) the external voltage VPP higher than the external voltage VCC, and executes a predetermined operation.

In addition, as a result of adopting the negative voltage as the threshold voltage of the memory cell, the upper limit values of intermediate voltages such as the non-selected voltages VREAD and VPASS using the external voltage VPP tend to decrease.

When the voltage generator generates a voltage for operation of the memory device using the external voltage VPP, it is difficult to reduce power consumption of the memory device.

For example, as an index, when a ratio (VCC/VPP) of the external voltage VCC to the external voltage VPP is larger than a current efficiency (Ieff) of the charge pump, the power consumption in the operation mode using the external voltage VPP is smaller than the power consumption in the operation mode using the charge pump.

More specifically, it is expressed by the following Formulas (F1) to (F5).

When the external voltage VPP is used, a power consumption Ppp of the external voltage VPP in the power supply is expressed by the following Formula (F1).

$$Ppp = VPP \times Iout 1 \qquad ( F1 )$$

In Formula (F1), “Iout1” is a current generated by the external voltage VPP.

When the voltage obtained by boosting the external voltage VCC by the charge pump is used, a power consumption Pext of the charge pump is expressed by the following Formula (F2).

$$\begin{matrix}Pext = VCC \times Iext \\ = VCC \times ( Iout 2 / Ieff )\end{matrix} \qquad ( F2 )$$

In Formula (F2), “Text” is a current flowing from the voltage terminal of the external voltage VCC to the input node of the charge pump, and “Iout2” is a current output from the output node of the charge pump.

From Formula (F2), the current efficiency of the charge pump is expressed by the following expression (F3).

$$Ieff = Iout 2 / Iext \qquad ( F3 )$$

When a relationship in which the power consumption Ppp is smaller than the power consumption Pext (Ppp<Pext) is satisfied, a relationship of the following Formula (F4) is obtained.

$$VPP \times Iout 1 < VCC \times ( Iout 2 / Ieff ) \qquad ( F4 )$$

As a result, the relationship of the following Formula (F5) is obtained based on Formula (F4).

$$Ieff < VCC / VPP \qquad ( F5 )$$

In this way, by satisfying the relationship of Formula (F5), the power consumption in the operation mode using the external voltage VPP becomes smaller than the power consumption in the operation mode using the charge pump.

The memory device 1 of the present embodiment includes a plurality of voltage generation modes. The memory device 1 of the present embodiment executes the voltage generation mode in which an operation is switched from generation of a voltage by the charge pump 99 to generation of a voltage by the external voltage VPP during generation of the operating voltage (during output of the operating voltage) in the charge pump circuit 171 (voltage generator 170).

As described above, the memory device 1 of the present embodiment executes the generation of the voltage by the charge pump 99 before the generation of the voltage by the external voltage VPP during the voltage generation operation. As a result, the memory device 1 of the present embodiment can appropriately switch the operation mode of the voltage generation in the low voltage range of the charge pump circuit 171 of the voltage generator 170. As a result, the memory device 1 of the present embodiment can reduce the power consumption occurring when the voltage is generated using the external voltage VPP.

In addition, in a case where one of the modes for generating a voltage can be selected as in the memory device 1 of the present embodiment, the memory device 1 can be operated in a more suitable mode according to the specifications of the memory device and the memory system.

As described above, the memory device of the present embodiment can be improved in characteristics.

### (2) Second Embodiment

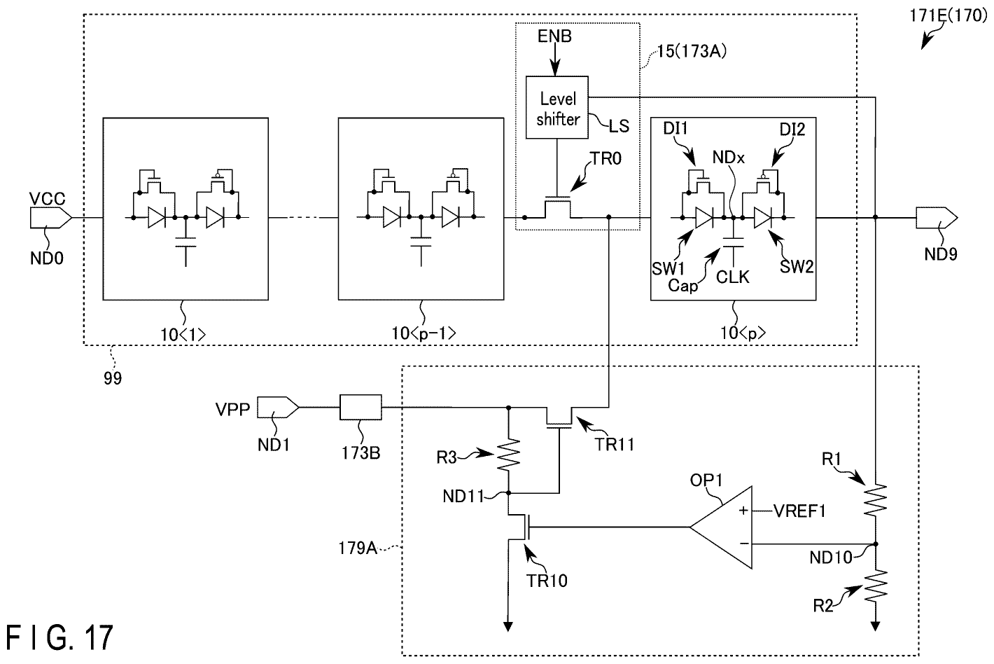

A memory device of a second embodiment will be described with reference to FIGS. 17 to 20.

### (a) Configuration Example

FIG. 17 is a circuit diagram illustrating an internal configuration of the charge pump circuit 171E of the voltage generator 170 in the memory device 1 of the present embodiment.

In FIG. 17, when the charge pump circuit 171E operates using the external voltage VPP, the charge pump circuit 171E charges an internal node of the charge pump 99 with the external voltage VPP.

As shown in FIG. 17, the charge pump circuit 171E includes the charge pump 99 and a regulator 179A.

The charge pump 99 includes a plurality of pump circuits 10 (10<1>, . . . , 10<p−1>, and 10<p>) and a switch circuit 15.

The p pump circuits 10<1>, . . . , 10<p−1>, and 10<p> are connected in series between the voltage node ND0 of the voltage generator 170 (charge pump circuit 171E) and an output node ND9 of the charge pump circuit 171E. p is a natural number of 2 or more. One pump circuit 10 corresponds to one pump stage.

An input node of the first (first stage) pump circuit 10<1> is connected to the voltage node ND0. An output node (output node of the charge pump 99) of the p-th (final stage) pump circuit 10<p> is connected to the output node ND9.

The switch circuit 15 is provided between the (p−1)-th pump circuit 10<p−1> and the p-th pump circuit 10<p>. The switch circuit 15 controls connection and separation between the voltage node ND0 to which the external voltage VCC is supplied and the output node ND9 substantially similarly to the switch circuit 173A described above. The switch circuit 15 includes a transistor TR0 and a level shifter LS.

The transistor TR0 is, for example, an N-type field effect transistor. One end of a current path of the transistor TR0 is connected to an output node of the (p−1)-th pump circuit 10<p−1>. The other end of the current path of the transistor TR0 is connected to an input node of the p-th pump circuit 10<p>.

An output node of the level shifter LS is connected to a gate of the transistor TR0. An input node of the level shifter LS is connected to the output node of the p-th pump circuit. An enable signal ENB is supplied to the control node of the level shifter LS.

The level shifter LS is activated according to the enable signal ENB. The activated level shifter LS converts the level of the voltage supplied to the input node of the level shifter LS. The activated level shifter LS supplies the level-converted voltage from the output node of the level shifter LS to the gate of the transistor TR0.

The transistor TR0 is turned on or off according to the voltage from the level shifter LS.

For example, in a case where the charge pump voltage VPUMP of the charge pump 99 is selected according to the voltage generation mode of the charge pump circuit 171E, the level shifter LS is activated by the enable signal ENB, and the transistor TR0 is set to the ON state. As a result, the p-th pump circuit 10<p> is connected to the (p−1)-th pump circuit 10<p−1> by the transistor TR0 in the ON state.

For example, in a case where the external voltage VPP is selected according to the voltage generation mode of the charge pump circuit 171E, the level shifter LS is deactivated by the enable signal ENB, and the transistor TR0 is set to the OFF state. As a result, the p-th pump circuit 10<p> is separated from the (p−1)-th pump circuit 10<p−1> by the transistor TR0 in the OFF state.

The regulator 179A is a linear regulator. The regulator 179A monitors the voltage (potential) of the output node ND9. The regulator 179A controls the voltage (potential) of a node ND10 by negative feedback control.

The regulator 179A includes an operational amplifier OP1, transistors TR10 and TR11, and resistors R1, R2, and R3.

One node of the resistor R1 is connected to the output node ND9 of the charge pump circuit 171E. The other node of the resistor R1 is connected to the node ND10. One node of the resistor R2 is connected to the node ND10. The other node of the resistor R2 is connected to a ground node.

One input node (inverting input terminal) of the operational amplifier OP1 is connected to the node ND10. The other input node (non-inverting input terminal) of the operational amplifier OP1 receives a voltage VREF1. An output node of the operational amplifier OP1 is connected to a gate of the transistor TR10.

One end of a current path of the transistor TR10 is connected to the ground node. The other end of the current path of the transistor TR10 is connected to a node ND11.

One node of the resistor R3 is connected to the node ND11. The other node of the resistor R3 is connected to the voltage node ND1 of the voltage generator 170 (charge pump circuit 171E).

A gate of the transistor TR11 is connected to the node ND11. One end of a current path of the transistor TR11 is connected to the voltage node ND1. The other end of the current path of the transistor TR11 is connected between an input node of the final-stage pump circuit 10<p> and an output node of the switch circuit 15.

The external voltage VPP is applied to the voltage node ND1. The external voltage VPP is output from the regulator 179A to the final-stage pump circuit 10<p>.

The regulator 179A adjusts the magnitude (voltage value) of the voltage output from the charge pump circuit 171E according to the monitoring result of the voltage of the output node ND9.

In the present embodiment, each pump circuit 10 includes at least two charge transfer switches SW1 and SW2, a capacitor Cap, and transistors DI1 and DI2.

The two charge transfer switches SW1 and SW2 are connected in series in the pump circuit 10. One node of the charge transfer switch SW1 as one switch is connected to an input node of the pump circuit 10. The other node of the charge transfer switch SW1 is connected to an internal node NDx of the pump circuit 10. One node of the charge transfer switch SW2 as the other switch is connected to the internal node NDx. The other node of the charge transfer switch SW2 is connected to an output node of the pump circuit 10.

One node of the capacitor Cap is connected to the internal node NDx. The other node of the capacitor Cap is connected to a node (clock node) to which a clock signal (or an inverted signal of the clock signal) CLK is supplied. The other end of the capacitor Cap may be connected to a voltage node to which a predetermined voltage (for example, the voltage VCC) is applied.

The transistor DI (DI1 and DI2) is connected in parallel to charge transfer paths (current paths) of the charge transfer switches SW1 and SW2. The transistor DI is diode-connected. One end (drain) of a current path of the transistor DI is connected to a gate of the transistor DI. Hereinafter, the transistor having the diode-connected terminals is also referred to as diode-connected transistor.

One end of the current path of the diode-connected transistor DI1 is connected to one node of the charge transfer switch SW1. The other end of the current path of the diode-connected transistor DI1 is connected to the other node of the charge transfer switch SW1.

One end of the current path of the diode-connected transistor DI2 is connected to one node of the charge transfer switch SW2. The other end of the current path of the diode-connected transistor DI2 is connected to the other node of the charge transfer switch SW2.

The first to (p−1)-th pump circuits 10<1>, . . . , and 10<p−1> may not include the diode-connected transistor DI.

The charge transfer switches SW1 and SW2 include transistors TR1 and TR2 having a triple well structure of FIG. 7.

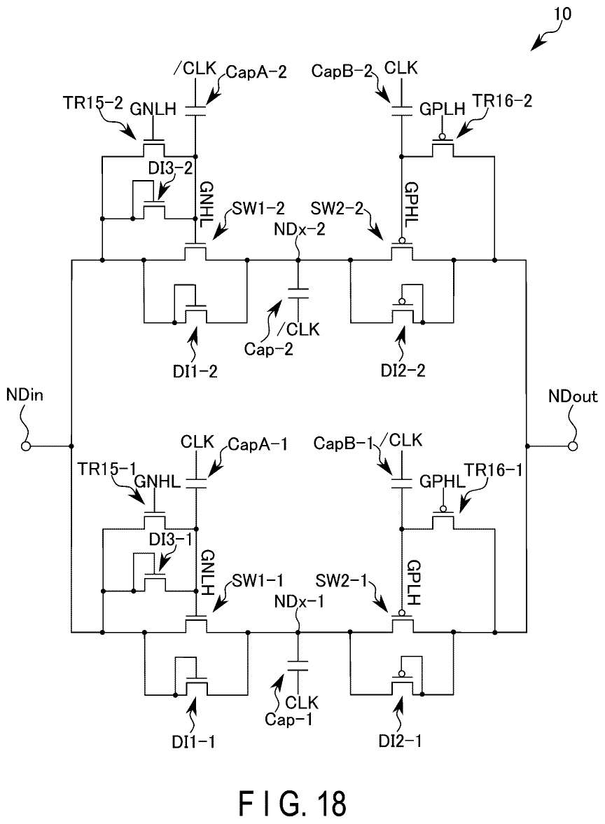

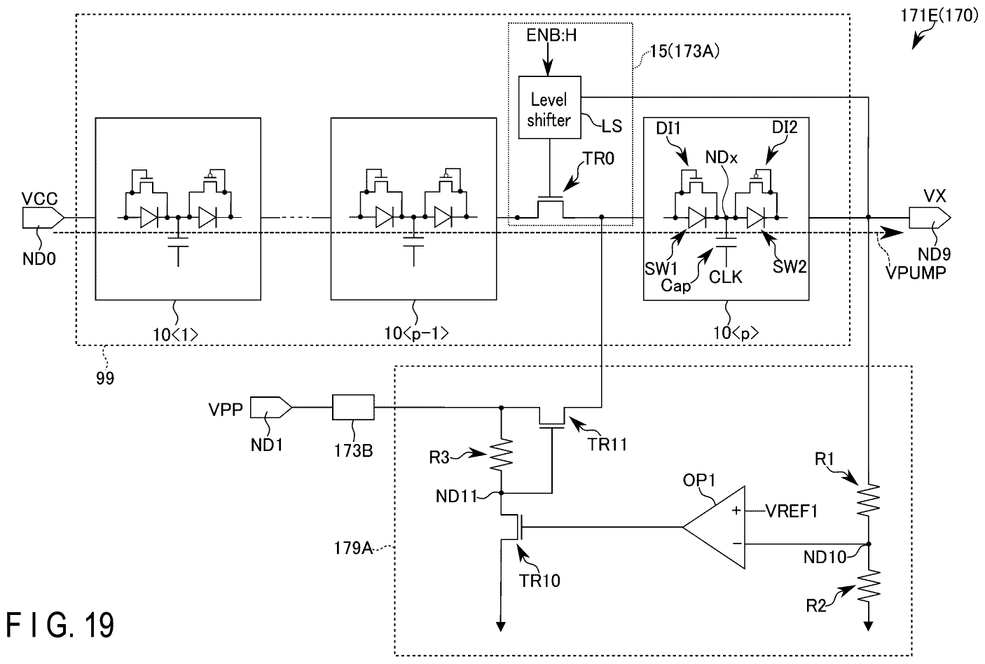

FIG. 18 is a circuit diagram illustrating a specific example of an internal configuration of the pump circuit 10.

As illustrated in FIG. 18, the pump circuit 10 includes charge transfer switches SW1-1, SW1-2, SW2-1, and SW2-2, transistors DI1-1, DI1-2, DI2-1, DI2-2, DI3-1, and DI3-2, transistors TR15-1, TR15-2, TR16-1, and TR16-2, and capacitors Cap-1, Cap-2, CapA-1, CapA-2, CapB-1, and CapB-2.

The charge transfer switch SW1-1 is an N-type field effect transistor. One end of the charge transfer path of the charge transfer switch SW1-1 is connected to an input node NDin of the pump circuit 10. The other end of the charge transfer path of the charge transfer switch SW1-1 is connected to an internal node NDx-1. A gate of the charge transfer switch SW1-1 receives a signal GNLH corresponding to the potential variation of the capacitor CapA-1 which will be described later and the operation of the transistor TR15-1 which will be described later.

The charge transfer switch SW2-1 is a P-type field effect transistor. One end of the charge transfer path of the charge transfer switch SW2-1 is connected to the internal node NDx-1. The other end of the charge transfer path of the charge transfer switch SW2-1 is connected to an output node NDout of the pump circuit 10. A gate of the charge transfer switch SW2-1 receives a signal GPLH corresponding to the potential variation of the capacitor CapB-1 which will be described later and the operation of the transistor TR16-1 which will be described later.

One node of the capacitor Cap-1 is connected to the internal node NDx-1. The other node of the capacitor Cap-1 is connected to the clock node to which the clock signal CLK is supplied.

One node of the capacitor CapA-1 is connected to the gate of the charge transfer switch SW1-1. The other node of the capacitor CapA-1 is connected to the clock node.

One node of the capacitor CapB-1 is connected to the gate of the charge transfer switch SW2-1. The other node of the capacitor CapB-1 is connected to a node (inverted clock node) to which the inverted signal/CLK of the clock signal CLK is supplied.

The transistor TR15-1 is an N-type field effect transistor. One end of a current path of the transistor TR15-1 is connected to the input node NDin. The other end of the current path of the transistor TR15-1 is connected to the gate of the charge transfer switch SW1-1. A gate of the transistor TR15-1 receives a control signal GNHL. The control signal GNHL is a signal corresponding to the potential variation of the capacitor CapA-2 which will be described later and the operation of the transistor TR15-2 which will be described later.

The transistor TR16-1 is a P-type field effect transistor. One end of a current path of the transistor TR16-1 is connected to the gate of the charge transfer switch SW2-1. The other end of the current path of the transistor TR16-1 is connected to the output node NDout. A gate of the transistor TR16-1 receives a control signal GPHL. The control signal GPHL is a signal corresponding to the potential variation of the capacitor CapB-2 which will be described later and the operation of the transistor TR16-2 which will be described later.

The diode-connected transistor DI1-1 is an n-type field effect transistor. The diode-connected transistor DI1-1 is connected in parallel to the charge transfer path (current path) of the charge transfer switch SW1-1. One end of a current path of the diode-connected transistor DI1-1 is connected to one end of the charge transfer path of the charge transfer switch SW1-1. The other end of the current path of the diode-connected transistor DI1-1 is connected to the other end of the charge transfer path of the charge transfer switch SW1-1. A gate of the diode-connected transistor DI1-1 is connected to one end of the current path of the diode-connected transistor DI1-1.

The diode-connected transistor DI2-1 is a p-type field effect transistor. The diode-connected transistor DI2-1 is connected in parallel to the charge transfer path of the charge transfer switch SW2-1. One end of a current path of the diode-connected transistor DI2-1 is connected to the other end of the charge transfer path of the charge transfer switch SW2-1. The other end of the current path of the diode-connected transistor DI2-1 is connected to one end of the charge transfer path of the charge transfer switch SW2-1. A gate of the diode-connected transistor DI2-1 is connected to one end of the current path of the diode-connected transistor DI2-1.

The diode-connected transistor DI3-1 is an n-type field effect transistor. The diode-connected transistor DI3-1 is connected in parallel to the current path of the transistor TR15-1. One end of a current path of the diode-connected transistor DI3-1 is connected to one end of the current path of the transistor TR15-1. The other end of the current path of the diode-connected transistor DI3-1 is connected to the other end of the current path of the transistor TR15-1. A gate of the diode-connected transistor DI3-1 is connected to one end of the current path of the diode-connected transistor DI3-1.

The charge transfer switch SW1-2 is an N-type field effect transistor. One end of the current path of the charge transfer switch SW1-2 is connected to an input node NDin of the pump circuit 10. The other end of the current path of the charge transfer switch SW1-2 is connected to an internal node NDx-2. The charge transfer switch SW1-2 receives the control signal GNHL.

The charge transfer switch SW2-2 is a P-type field effect transistor. One end of a current path of the charge transfer switch SW2-2 is connected to the internal node NDx-2. The other end of the current path of the charge transfer switch SW2-2 is connected to the output node NDout of the pump circuit 10. The charge transfer switch SW2-2 receives the control signal GPHL.

The charge transfer paths of the charge transfer switches SW1-2 and SW2-2 connected in series are connected in parallel to the charge transfer paths of the charge transfer switches SW1-1 and SW2-1 connected in series.

One node of the capacitor Cap-2 is connected to the internal node NDx-2. The other node of the capacitor Cap-2 is connected to the inverted clock node.

One node of the capacitor CapA-2 is connected to the gate of the charge transfer switch SW1-2. The other node of the capacitor CapA-2 is connected to the inverted clock node.

One node of the capacitor CapB-2 is connected to the gate of the charge transfer switch SW2-2. The other node of the capacitor CapB-2 is connected to the clock node.

The transistor TR15-2 is an N-type field effect transistor. One end of a current path of the transistor TR15-2 is connected to the input node NDin. The other end of the current path of the transistor TR15-2 is connected to the gate of the charge transfer switch SW1-2. A gate of the transistor TR15-2 receives the control signal GNLH.

The transistor TR16-2 is a P-type field effect transistor. One end of a current path of the transistor TR16-2 is connected to the gate of the charge transfer switch SW2-2. The other end of the current path of the transistor TR16-2 is connected to the output node NDout. A gate of the transistor TR16-2 receives the control signal GPLH.

The diode-connected transistor DI1-2 is an n-type field effect transistor. The diode-connected transistor DI1-2 is connected in parallel to the charge transfer path of the charge transfer switch SW1-2. One end of a current path of the diode-connected transistor DI1-2 is connected to one end of the charge transfer path of the charge transfer switch SW1-2. The other end of the current path of the diode-connected transistor DI1-2 is connected to the other end of the charge transfer path of the charge transfer switch SW1-2. A gate of the diode-connected transistor DI1-2 is connected to one end of the current path of the diode-connected transistor DI1-2.

The diode-connected transistor DI2-2 is a p-type field effect transistor. The diode-connected transistor DI2-2 is connected in parallel to the charge transfer path of the charge transfer switch SW2-2. One end of the current path of the diode-connected transistor DI2-2 is connected to the other end of the charge transfer path of the charge transfer switch SW2-2. The other end of the current path of the diode-connected transistor DI2-2 is connected to one end of the charge transfer path of the charge transfer switch SW2-2. A gate of the diode-connected transistor DI2-2 is connected to one end of the current path of the diode-connected transistor DI2-2.

The diode-connected transistor DI3-2 is an n-type field effect transistor. The diode-connected transistor DI3-2 is connected in parallel to the current path of the transistor TR15-2. One end of a current path of the diode-connected transistor DI3-2 is connected to one end of the current path of the transistor TR15-2. The other end of the current path of the diode-connected transistor DI3-2 is connected to the other end of the current path of the transistor TR15-2. A gate of the diode-connected transistor DI3-2 is connected to one end of the current path of the diode-connected transistor DI3-2.

The diode-connected transistor may be connected in parallel to the current paths of the transistors TR16-1 and TR16-2. Instead of the diode-connected transistor DI, a diode such as a PN junction diode may be connected in parallel to the charge transfer path of the charge transfer switch SW.

The operation of the transistor TR15-1 is controlled by the control signal GNHL, and the operation of the transistor TR15-2 is controlled by the control signal GNLH. The operation of the transistor TR16-1 is controlled by the control signal GPHL, and the operation of the transistor TR16-2 is controlled by the control signal GPLH.

The pump circuit 10 executes voltage boosting (pump operation) by the clock signal CLK supplied to the clock node and the inverted clock signal/CLK supplied to the inverted clock node.

When the operating voltage is generated using the external voltage VPP, the operation of the pump circuit 10 of the charge pump 99 is stopped.

If the external voltage VPP is selected as the output voltage of the charge pump circuit 171E, the external voltage VPP is output to the outside of the charge pump circuit 171E (voltage generator 170) via the final-stage pump circuit 10<p> of the charge pump 99.

The external voltage VPP is supplied to the final-stage pump circuit 10<p>. In the pump circuit 10<p>, the external voltage VPP passes through the current path of the diode-connected transistor DI and is output from the pump circuit 10<p>. The pump circuit 10<p> functions as a path switch (voltage path) between the output node ND9 and the regulator 179A.

The nodes NDx, NDin, and NDout of the final-stage pump circuit 10<p> are charged by the supply of the external voltage VPP.

### (b) Operation Example

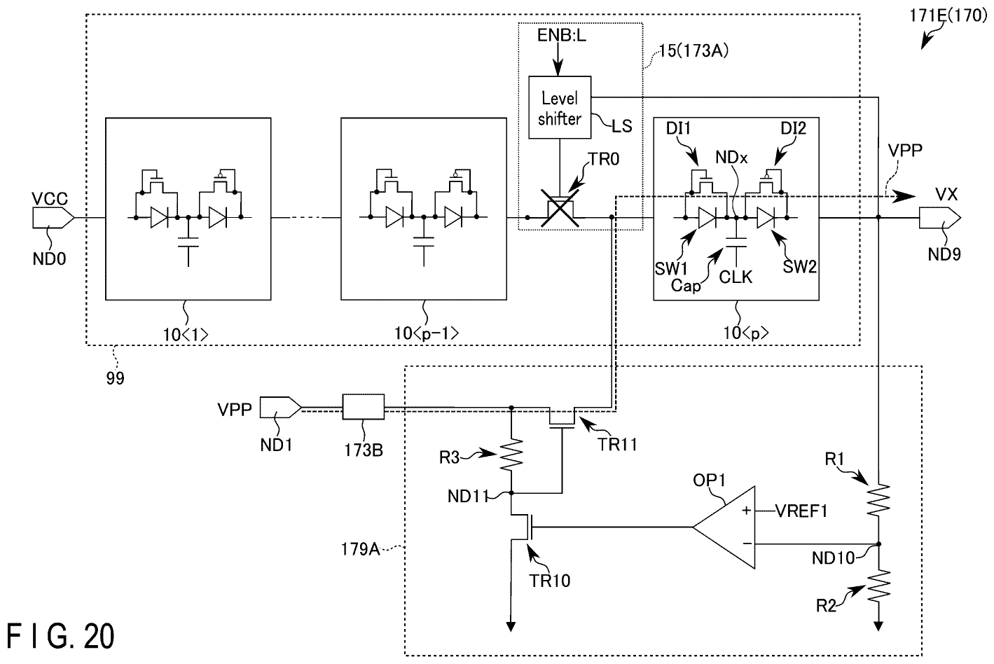

An operation example of the memory device 1 of the present embodiment will be described with reference to FIGS. 19 and 20.

FIG. 19 is a schematic diagram for explaining an operation state of the charge pump circuit 171E when the charge pump voltage VPUMP from the charge pump 99 is selected (output).

As illustrated in FIG. 19, the level shifter LS is activated by the enable signal ENB at a first level (for example, “H” level). Accordingly, the transistor TR0 is turned on.

The final-stage (p-th) pump circuit 10<p> is connected to the pump circuits 10<1>, . . . , and 10<p−1> via the transistor TR0 in the ON state.

The voltage node ND1 is electrically separated from the charge pump 99 and the node ND9 by the switch circuit 173B in the OFF state.

The charge pump 99 boosts the external voltage VCC by the pump circuit 10 of the pump stages. The charge transfer switches SW1-1, SW1-2, SW2-1, and SW2-2 are activated by the control signals GNLH, GNHL, GPLH, and GPHL.

As a result, the charge pump voltage VPUMP is output from the charge pump 99 through the charge transfer path of the charge transfer switch SW.

The regulator 179A monitors the output voltage from the pump circuit 10<p>. As a result, the regulator 179A adjusts the voltage of the node ND10 by negative feedback control.

The charge pump circuit 171E outputs the voltage VX from the output node ND9. For example, the voltage VX is supplied to the sense amplifier circuit 150.

FIG. 20 is a schematic diagram for explaining an operation state of the charge pump circuit 171E when the external voltage VPP is selected (output).

As illustrated in FIG. 20, the level shifter LS is deactivated by the enable signal ENB at a second level (for example, “L” level) different from the first level. Accordingly, the transistor TR0 is turned off.

The final-stage pump circuit 10<p> is electrically separated from the pump circuits 10<1>, . . . , and 10<p−1> by the transistor TR0 in the OFF state. The switch circuit 15 cuts off the supply of the external voltage VCC to the pump circuit 10<p>.

The voltage node ND1 is electrically connected to the charge pump 99 and the node ND9 by the switch circuit 173B in the ON state.

The external voltage VPP is supplied to the pump circuit 10<p> via the transistor TR11.

When the external voltage VPP is output in the voltage generation mode, the clock signal supplied to the clock node is stopped. The charge transfer switches SW1 and SW2 are deactivated by the control signals GNLH, GNHL, GPLH, and GPHL.

As described above, in the voltage generator 170 of the memory device 1 of the present embodiment, the pump circuit 10 of the charge pump circuit 171E includes the diode-connected transistors (diodes) DI1 and DI2 connected in parallel to the charge transfer switches SW1 and SW2.

In the pump circuit 10<p>, the external voltage VPP supplied to the pump circuit 10<p> passes through the diode-connected transistor DI and is transferred from the input node NDin to the output node NDout of the pump circuit 10<p>.

Each of the nodes NDin, NDout, and NDx of the final-stage pump circuit 10<p> are charged by the external voltage VPP. As a result, the source/drain layers 71 of the charge transfer switches SW1 and SW2 are charged. The voltage transfer path of the external voltage VPP via the pump circuit 10<p> is gradually charged by the monitoring operation of the regulator 179A.

In the regulator 179A, the operational amplifier OP1 supplies a signal corresponding to the voltage of the node ND10 to the gate of the transistor TR10. The transistor TR10 causes a current having a magnitude corresponding to the signal from the operational amplifier OP1 to flow. As a result, the voltage of the node ND11 fluctuates. The transistor TR11 transfers the external voltage VPP to the output node ND9 via the pump circuit 10<p> by a driving force corresponding to the voltage of the node ND11.

As described above, in the present embodiment, the external voltage VPP is output from the charge pump circuit 171E (voltage generator 170) via the final-stage pump circuit 10<p> of the charge pump 99.

Although an example of the charge pump circuit 171E that generates the voltage VX to be supplied to the sense amplifier circuit 150 is illustrated in the second embodiment, the circuit configurations of FIGS. 17 and 18 and the operations of FIGS. 19 and 20 may be applied to other charge pump circuits 171A, 171B, 171C, and 171D.

### (c) Summary

According to the operation mode of the charge pump circuit 171 in the voltage generator 170, the external voltage VPP higher than the external voltage VCC is supplied to the output node ND9 of the voltage generator 170 (charge pump circuit 171).

In a charge pump of a voltage generator of a general memory device, when a low breakdown voltage transistor is used for a charge transfer switch, a high external voltage VPP is applied to a source/drain of the low breakdown voltage transistor of a final-stage pump circuit. When breakdown voltage violation of the low breakdown voltage transistor occurs upon application of the external voltage VPP, the low breakdown voltage transistor may be destroyed.

In the memory device 1 of the present embodiment, in the charge pump 99 in the charge pump circuit 171, the diode-connected transistor DI is connected in parallel to the charge transfer path of the charge transfer switch SW including the low breakdown voltage transistor.

When the charge pump 99 is deactivated (not driven), the diode-connected transistor DI charges the nodes NDx, NDin, and NDout of the charge transfer switch (low breakdown voltage transistor) SW by the external voltage VPP transferred to the output node ND9 of the charge pump circuit 171E.

As a result, the memory device 1 of the present embodiment can avoid the breakdown voltage violation of the low breakdown voltage transistor SW (LV) in the voltage generator 170 at the time of voltage generation.

As a result, the memory device 1 of the present embodiment can suppress destruction of the circuits in the memory device 1.

The memory device 1 of the present embodiment can be improved in reliability along with the suppression of the destruction of the circuits in the memory device 1.

As described above, the memory device 1 of the present embodiment can be improved in characteristics.

### (3) Third Embodiment

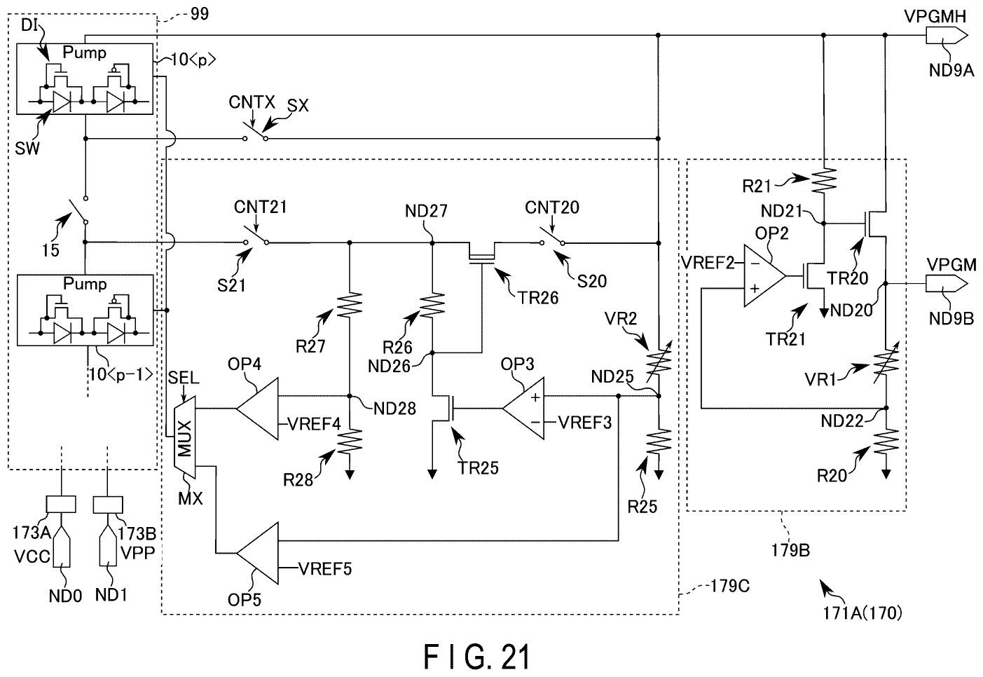

A memory device of a third embodiment will be described with reference to FIGS. 21 to 23.

### (a) Configuration Example

FIG. 21 is a circuit diagram illustrating an internal configuration of the charge pump circuit 171A of the voltage generator 170 in the memory device 1 of the present embodiment.

For example, the charge pump circuit 171A in FIG. 21 generates a program voltage VPGM and a voltage VPGMH equal to or higher than the program voltage VPGM during the program operation. The voltage VPGMH is a voltage to be supplied to the control terminal (gate terminal) of the transfer gate HV in the row control circuit 140. By the supply of the voltage VPGMH, the transfer gate HV can transfer the program voltage VPGM.

The charge pump circuit 171A in FIG. 21 can execute an operation for voltage generation in an operation mode (hereinafter, referred to as low ripple mode) in which a voltage VPGM (and the program voltage VPGM) having a low ripple can be output.

As illustrated in FIG. 21, the charge pump circuit 171A includes the charge pump 99, regulators 179B and 179C, and a switch SX.

The charge pump 99 includes a plurality of pump circuits 10. As illustrated in FIGS. 17 and 18 described above, the pump circuit 10 includes the charge transfer switches SW1 and SW2, the capacitor Cap, and the diode-connected transistor DI. The diode-connected transistor DI is connected in parallel to the charge transfer path of the charge transfer switch SW.

For example, in the charge pump 99 that generates the program voltage VPGM, the external voltage VPP may be supplied to the charge pump 99. The switch circuit 173B is provided between the voltage node ND1 and the charge pump 99. The switch circuit 173A is provided between the voltage node ND0 and the charge pump 99. The charge pump 99 boosts the supplied external voltage VPP and generates a voltage (for example, voltage VPGMH) higher than the external voltage VPP.

The external voltage VPP may be transferred to the output nodes ND9A and ND9B of the charge pump circuit 171A (voltage generator 170) without passing through the charge pump 99 according to the voltage generation mode.

The regulator 179B is a linear regulator. The regulator 179B includes an operational amplifier OP2, transistors TR20 and TR21, a variable resistor VR1, and resistors R20 and R21.

The transistor TR20 is an N-type field effect transistor. One end of a current path of the transistor TR20 is connected to an output node (output node of the charge pump 99) ND9A of the charge pump circuit 171A. The other end of the current path of the transistor TR20 is connected to a node ND20. A gate of the transistor TR20 is connected to the node ND21. The node ND20 is connected to an output node (output node of the regulator 179B) ND9B of the charge pump circuit 171A.

One node of the variable resistor VR1 is connected to the node ND20. The other node of the variable resistor VR1 is connected to a node ND22.

One node of the resistor R20 is connected to the node ND22. The other node of the resistor R20 is connected to a ground node.

One input node (non-inverting input terminal) of the operational amplifier OP2 is connected to the node ND22. The other input node (inverting input terminal) of the operational amplifier OP2 receives a voltage VREF2. An output node of the operational amplifier OP2 is connected to a gate of the transistor TR21.

The transistor TR21 is an N-type field effect transistor. One end of the current path of the transistor TR21 is connected to a node ND21. The other end of a current path of the transistor TR22 is connected to the ground node.

One node of the resistor R21 is connected to the node ND21. The other node of the resistor R21 is connected to the output node ND9A.

The regulator 179B receives the voltage VPGMH. The regulator 179B adjusts and steps down the voltage VPGMH by an operation of the operational amplifier OP2. As a result, the regulator 179B outputs the program voltage VPGM equal to or lower than the voltage VPGMH.

The regulator 179C is a linear regulator. The regulator 179C includes operational amplifiers OP3, OP4, and OP5, transistors TR25 and TR26, a variable resistor VR2, resistors R25, R26, R27, and R28, and switches S20 and S21.

One node of the variable resistor VR2 is connected to the output node ND9A. The other node of the variable resistor VR2 is connected to a node ND25.

One node of the resistor R25 is connected to the node ND25. The other node of the resistor R25 is connected to a ground node.

One input node (non-inverting input terminal) of the operational amplifier OP3 is connected to the node ND25. The other input node (inverting input terminal) of the operational amplifier OP3 receives a voltage VREF3. An output terminal of the operational amplifier OP3 is connected to a gate of the transistor TR25.

The transistor TR25 is an N-type field effect transistor. One end of a current path of the transistor TR25 is connected to the ground node. The other end of the current path of the transistor TR25 is connected to a node ND26.

One node of the resistor R26 is connected to the node ND26. The other node of the resistor R26 is connected to a node ND27.

The transistor TR26 is a depression type transistor. A gate of the transistor TR26 is connected to the node ND26. One end of a current path of the transistor TR26 is connected to the node ND27. The other end of the current path of the transistor TR26 is connected to one node of the switch S20. The other node of the switch S20 is connected to the output node ND9A of the charge pump circuit 171A. The switch S20 is turned on and off according to a control signal CNT20.

One node of the switch S21 is connected to the node ND27. The other node of the switch S21 is connected between the output node of the (p−1)-th pump circuit 10<p−1> and the input node of the switch circuit 15. The switch S21 is turned on and off according to a control signal CNT21.

One node of the resistor R27 is connected to the node ND27. The other node of the resistor R27 is connected to a node ND28. One node of the resistor R28 is connected to the node ND28. The other node of the resistor R28 is connected to a ground node.

The operational amplifier OP4 is a comparator. One input node of the operational amplifier OP4 is connected to the node ND28. The other input node of the operational amplifier OP4 receives a voltage VREF4. An output node of the operational amplifier OP4 is connected to one input node of a multiplexer MX.

The operational amplifier OP5 is a comparator. One input node of the operational amplifier OP5 is connected to the node ND25. The other input node of the operational amplifier OP5 receives a voltage VREF5. An output node of the operational amplifier OP5 is connected to the other input node of the multiplexer MX.

An output node of the multiplexer MX is connected to a control node of each pump circuit 10. The multiplexer MX selects one of the outputs of the two operational amplifiers OP4 and OP5 according to a control signal SEL. The pump circuit 10 executes an operation according to an output signal of the multiplexer MX.

The regulator 179C adjusts the voltage in the low ripple mode. The regulator 179C adjusts the voltage output from the (p−1)-th pump circuit 10<p−1> in the low ripple mode. For example, the voltage generated in the low ripple mode is generated by the operations from the first pump circuit 10<1> to the (p−1)-th pump circuit 10<p−1>.

One node of the switch SX is connected to the output node ND9A. The other node of the switch SX is connected between the input node of the last-stage pump circuit 10<p> and the switch circuit 15. The switch SX is turned on and off according to a control signal CNTX. The switch SX is set to the OFF state during the voltage generation operation of the charge pump circuit 171A in the above-described voltage generation modes. The switch SX is set to the ON state in the low ripple mode. By the switch SX in the ON state, the output voltage of the (p−1)-th pump circuit 10<p−1> is supplied to the final-stage pump circuit 10<p> in a deactivated state (non-driven state). In the pump circuit 10<p>, the charge transfer switch SW including the low breakdown voltage transistor is charged by the voltage from the switch SX.

### (b) Operation Example

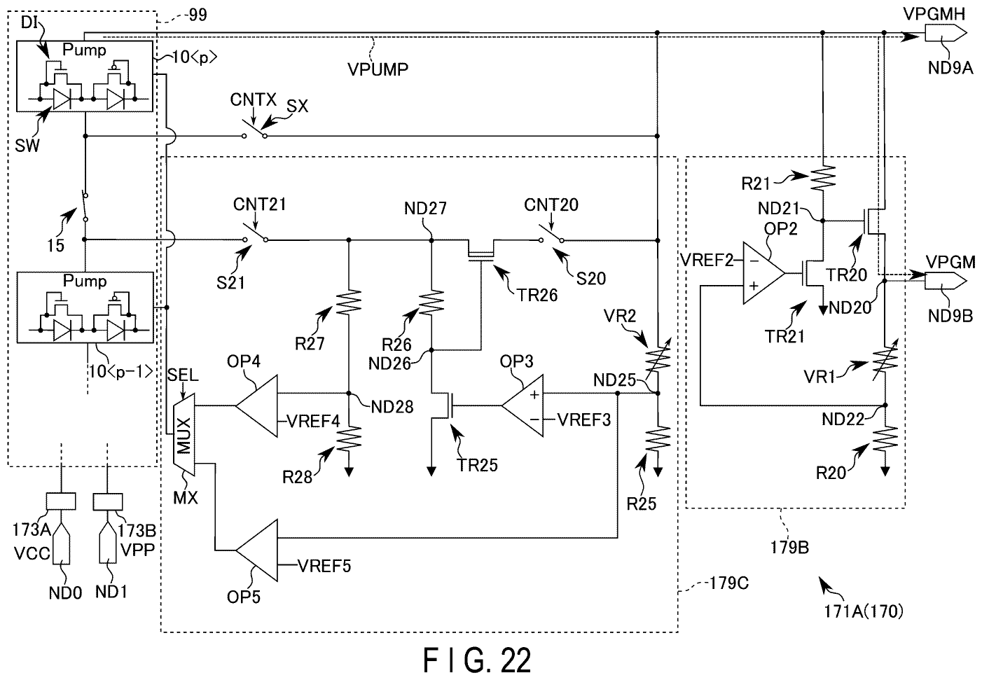

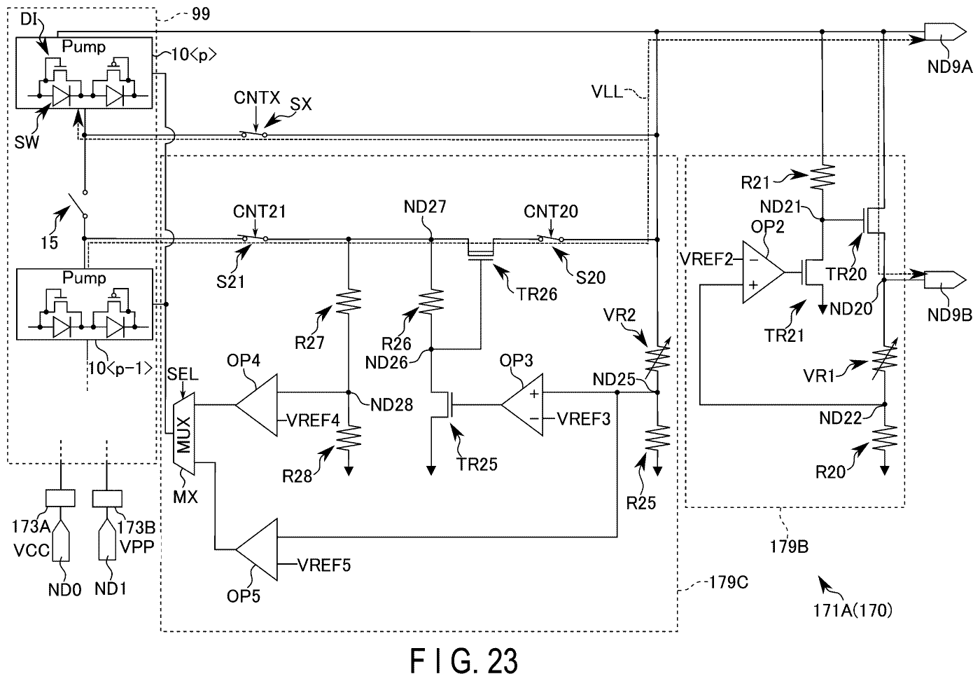

An operation example of the memory device of the present embodiment will be described with reference to FIGS. 22 and 23.

(b-1) Voltage Generation Mode

FIG. 22 is a schematic diagram for explaining an operation state of the charge pump circuit 171A when the charge pump voltage VPUMP from the charge pump 99 is output.

As illustrated in FIG. 22, in the regulator 179C, the switches S20 and S21 are set to OFF states by the control signals CNT20 and CNT21. The switch SX is set to the OFF state by the control signal CNTX. For example, in the regulator 179C, the multiplexer MX selects a signal from the operational amplifier OP5 by the control signal SEL. The operational amplifier OP5 outputs a signal having a level corresponding to the voltage of the node ND25 to the multiplexer MX. The multiplexer MX supplies the selected signal to each pump circuit 10 as the control signal. The pump circuits 10 operate in response to the signal from the multiplexer MX.

The switch circuit 15 is set to the ON state. As a result, the final-stage pump circuit 10<p> is connected to the preceding-stage pump circuit 10<p−1>. In the charge pump 99, the external voltage VCC is boosted by the pump circuits 10. The charge pump 99 supplies the boosted voltage to the output nodes ND9A and ND9B.

The charge pump circuit 171A outputs the charge pump voltage VPUMP as the voltage VPGMH from the output node ND9A to the row control circuit 140.

The regulator 179B adjusts (for example, steps down) the charge pump voltage VPUMP. In the regulator 179B, the operational amplifier OP2 supplies a signal corresponding to the voltage of the node ND22 to the gate of the transistor TR21. The transistor TR21 causes a current corresponding to the signal from the operational amplifier OP2 to flow. The transistor TR20 causes a current corresponding to the voltage of the node ND21 to flow. As a result, the magnitude of the voltage to be supplied to the output node ND9B is adjusted according to a driving force of the transistor TR20.

The charge pump circuit 171A outputs the voltage adjusted by the regulator 179B as the program voltage VPGM from the output node ND9B to the row control circuit 140.

In this manner, the charge pump voltage VPUMP from the charge pump 99 is supplied to the memory cell array 110.

The external voltage VPP may be boosted by the charge pump 99 to generate the voltages VPGMH and VPGM.

In a state where the operation of the charge pump 99 (or a part of the charge pump 99) is stopped during the operation of the memory device 1, the external voltage VPP may be supplied to the source/drain of the charge transfer switch SW in the final-stage pump circuit 10<p> by the above-described diode-connected transistor DI. As a result, destruction of the charge transfer switch SW is suppressed.

(b-2) Low Ripple Mode

FIG. 23 is a schematic diagram for explaining an operation state of the charge pump circuit 171A in the low ripple mode in the memory device 1 of the present embodiment.

As illustrated in FIG. 23, when the charge pump circuit 171A operates in the low ripple mode, the switches S20 and S21 are set to the ON states by the control signals CNT20 and CNT21.

The switch circuit 15 is set to the OFF state. As a result, the final-stage pump circuit 10<p> is electrically separated from the voltage node ND0. Therefore, the supply of the voltage from the preceding-stage pump circuit 10<p−1> to the pump circuit 10<p> is cut off.

The (p−1)-th pump circuit 10<p−1> is connected to the output nodes ND9A and ND9B via the switches S20 and S21 in the ON states. The pump circuit 10<p−1> supplies a voltage VLL to the output nodes ND9A and ND9B via the regulator 179C.

The regulator 179C monitors the voltage (voltage of the output node ND9A) output from the pump circuit 10<p−1>. In the regulator 179C, the operational amplifiers OP3 and OP5 operate according to the voltage of the node ND25. The operational amplifier OP3 supplies a signal corresponding to the voltage of the node ND25 to the gate of the transistor TR25. The transistor TR25 causes a current having a magnitude corresponding to the signal from the operational amplifier OP3 to flow. The voltage of the node ND26 fluctuates according to the current flowing from the transistor TR25. The transistor TR26 transfers the voltage from the pump circuit 10<p−1> by a driving force corresponding to the voltage of the node ND26.

The multiplexer MX selects the output of the operational amplifier OP4 based on the control signal SEL. The operational amplifier OP4 outputs a signal having a level corresponding to the voltage of the node ND28 to the multiplexer MX. The multiplexer MX supplies the signal from the operational amplifier OP4 to the pump circuits 10. The pump circuits 10 operate in response to the signal from the multiplexer MX.

The regulator 179C sends the adjusted voltage VLL to the output node ND9A. The voltage VLL is output from the charge pump circuit 171A.

The regulator 179B further adjusts the voltage VLL output from the regulator 179 C. The charge pump circuit 171A outputs the adjusted voltage from the output node ND9B.

In the low ripple mode, the charge pump circuit 171A of the voltage generator 170 supplies the generated voltage to the word line WL in the memory cell array 110 via the row control circuit 140.

In the present embodiment, in the low ripple mode, the switch SX is set to the ON state by the control signal CNTX. As a result, the input node of the last-stage pump circuit 10<p> is connected to an output node of the regulator 179C.

The switch SX in the ON state supplies the voltage output from the regulator 179C (voltage output from the pump circuit 10<p−1>) to the pump circuit 10<p>.

In the pump circuit 10<p> in the deactivated state (non-driven state), the diode-connected transistor DI supplies the voltage transferred from the switch SX to the source/drain (node) of the charge transfer switch SW. As a result, the source/drain of the charge transfer switch SW is charged. As a result, each node of the pump circuit 10<p> is charged.

Note that, in the present embodiment, an example of the charge pump circuit 171A that generates various voltages VPGMH and VPGM during the program operation is illustrated, but the circuit configuration and operation illustrated in FIGS. 21 to 23 may be applied to other charge pump circuits 171B, 171C, 171D, and 171E.

### (c) Summary

In the memory device 1 of the present embodiment, the pump circuit 10 of the charge pump 99 includes the diode-connected transistor DI. The diode-connected transistor DI is connected in parallel to the charge transfer path of the charge transfer switch SW.

In the low ripple mode, in the charge pump 99, the final-stage pump circuit 10<p> is electrically separated from the preceding-stage pump circuit 10<p−1>.

In the present embodiment, the switch SX is provided between the last-stage pump circuit 10<p> and the regulator 179C that outputs the voltage VLL.

The voltage VLL generated in the low ripple mode is supplied to the final-stage pump circuit 10<p> via the switch SX. The diode-connected transistor DI transfers the voltage VLL into the pump circuit 10<p>. As a result, an internal node (for example, source/drain) of the charge transfer switch of the pump circuit 10 is charged.

As a result, the memory device 1 of the present embodiment can suppress destruction of the charge transfer switch SW in the charge pump 99 during operation, for example, in the low ripple mode.

As described above, the memory device 1 of the present embodiment can be improved in characteristics.

### (4) Modification

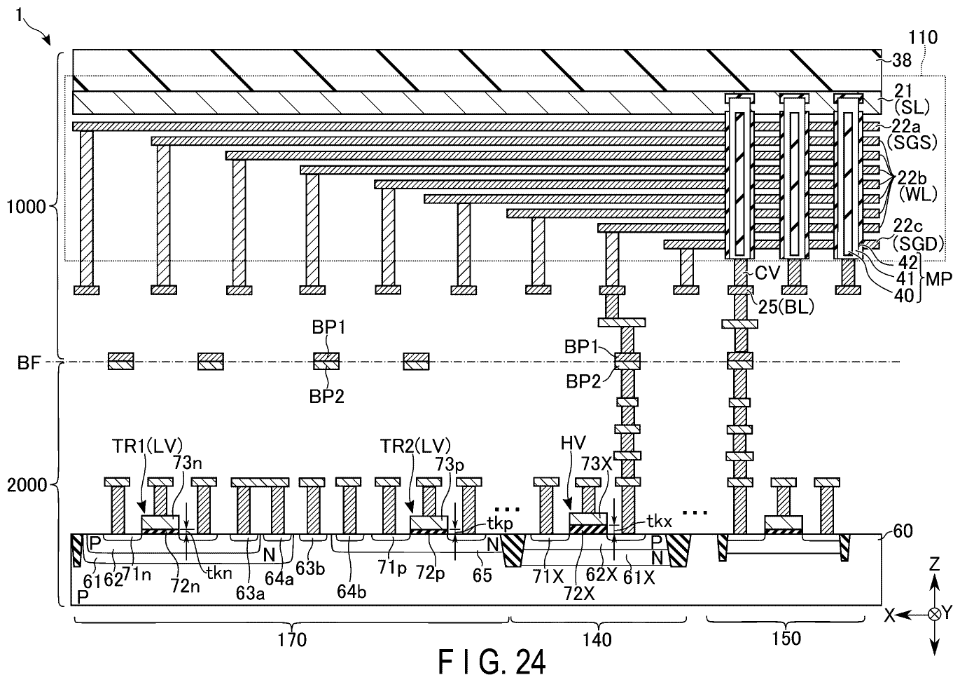

A modification of the memory device of the present embodiments will be described with reference to FIG. 24.

FIG. 24 is a cross-sectional view illustrating a structure of the modification of the memory device 1 of the present embodiments. In FIG. 24, an interlayer insulating film covering elements and interconnects of the memory device 1 is not illustrated.

As illustrated in FIG. 24, the memory device 1 of the embodiments may have a bond structure.

The memory device 1 having a bond structure has a structure in which a chip (hereinafter, referred to as memory cell array chip) 1000 on which the memory cell array 110 is formed is bonded to a chip (hereinafter, referred to as CMOS chip) 2000 on which a CMOS circuit is formed. Peripheral circuits of the memory device 1 such as the row control circuit 140, the sense amplifier circuit 150, and the voltage generator 170 are formed on the CMOS chip 2000.

For example, the transfer gate (high breakdown voltage transistor) HV of the row control circuit 140 is provided on the semiconductor substrate 60 together with the transistor TR used for the charge pump circuit 171.

The transfer gate HV has a triple well structure. In an area where the transfer gate HV is formed, an N-type well 61X is provided in the semiconductor substrate 60. A P-type well 62X is provided in the N-type well 61X. The N-type well 61X surrounds the P-type well 62X.

The transfer gate HV is disposed on the P-type well 62X. The transfer gate HV includes two source/drain layers 71X, a gate insulating film 72X, and a gate electrode 73X.

The source/drain layer (diffusion layer or impurity region) 71X is provided in the P-type well 62X. The gate insulating film 72X is provided on the P-type well 62X. The gate insulating film 72X is disposed on a channel region between the two source/drain layers 71X. The gate electrode 73X is provided on the gate insulating film 72X. The gate electrode 73X faces the channel region via the gate insulating film 72X.

A film thickness tkn of the gate insulating film 72n of the transistor TR1 and a film thickness tkp of the gate insulating film 72p of the transistor TR2 are thinner than a film thickness tkx of the gate insulating film 72X of the transfer gate HV. As a result, the breakdown voltage of the transfer gate HV becomes higher than the breakdown voltages of the transistors TR1 and TR2.

In the memory device 1 having a bond structure, the two chips 1000 and 2000 are in contact with each other on a surface (hereinafter, referred to as bond surface) BF between the chips.

In the bond surface BF, the memory cell array chip 1000 includes a plurality of pads (hereinafter, referred to as bond pads) BP1 for bond between the chips 1000 and 2000 on one surface of the chip (for example, an upper surface of the chip 1000) in the Z direction.

In the bond surface BF, the CMOS chip 2000 includes a plurality of pads (bond pads) BP2 for bond between the chips 1000 and 2000 on one surface of the chip 2000 (for example, an upper surface of the chip 2000) in the Z direction.

The bond pads BP1 and BP2 are conductors including copper (Cu). The bond pads BP1 and BP2 include an active pad connected to an element (interconnect) and a dummy pad not connected to the element.

The bond pad BP1 of the memory cell array chip 1000 is joined to the bond pad BP2 of the CMOS chip 2000 by a covalent bond generated between members forming the pads BP1 and BP2.

As a result, the memory cell array chip 1000 is bonded to the CMOS chip 2000 in the memory device 1 of the present embodiments.

The memory device 1 of the present modification includes the voltage generator 170 and the charge pump circuit 171 described above. The memory device 1 of the present modification can obtain the effects of the above-described embodiments.

### (5) Others

A voltage generator including a charge pump that generates a specific voltage and a regulator, in the memory devices of the above-described embodiments, has been exemplified. However, the configuration and function of the voltage generator in the memory device of the present embodiments are not limited to the type of the charge pump and the type of the regulator.

The memory device of the present embodiments may be a memory device other than the NAND flash memory.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device comprising:
a memory cell array including a plurality of memory cells; and
a voltage generator that is supplied with a first external voltage and a second external voltage higher than the first external voltage and generates an operating voltage of the memory cell array, wherein
an operation mode of the voltage generator at a time of generating a first voltage value of the operating voltage includes a first mode including a first period and a second period after the first period, and the first mode of generating the operating voltage using the first external voltage in the first period and using the second external voltage in the second period.

2. The memory device according to claim 1, wherein
in the first mode of the voltage generator, the first external voltage is boosted in the first period, and the second external voltage is stepped down in the second period.

3. The memory device according to claim 1, further comprising:
a first terminal to which the first external voltage is supplied and through which a first current flows; and
a second terminal to which the second external voltage is supplied and through which a second current flows, wherein
in the first mode, the first current has a first peak in the first period from start of generation of the operating voltage, and
the second current has a second peak within the second period.

4. The memory device according to claim 3, wherein
the operation mode of the voltage generator at the time of generating the first voltage value of the operating voltage further includes a second mode of generating the operating voltage using the first external voltage,
in the second mode, the first current has a third peak in a third period from the start of generation of the operating voltage, and
the first period is shorter than the third period.

5. The memory device according to claim 1, wherein
the voltage generator includes:
a charge pump that boosts the first external voltage;
a regulator that adjusts the second external voltage;
a first switch circuit provided between the charge pump and the regulator; and
a second switch circuit provided between a voltage node to which the second external voltage is supplied and the regulator.

6. The memory device according to claim 5, wherein
the charge pump includes a first transistor, and
the first transistor includes:
a semiconductor substrate of a first conductivity type;
a first well of a second conductivity type provided in the semiconductor substrate, the second conductivity type being different from the first conductivity type;
a second well of the first conductivity type provided in the first well;
first and second source/drain layers provided in the second well;
a first gate insulating film provided on a channel region between the first and second sources/drain layers; and
a first gate electrode provided on the first gate insulating film.

7. The memory device according to claim 6, further comprising:
a transfer gate connected to a word line of the memory cell array, wherein
the first gate insulating film is thinner than a gate insulating film of the transfer gate.

8. The memory device according to claim 1, wherein
the voltage generator generates a voltage to be applied to a non-selected word line in the memory cell array in a read operation or a write operation.

9. A memory device comprising:
a memory cell array including a plurality of memory cells; and
a voltage generator including a first node to which a first external voltage is supplied, a second node to which a second external voltage higher than the first external voltage is supplied, and a third node that outputs an operating voltage of the memory cell array, the voltage generator generating the operating voltage using at least one of the first and second external voltages, wherein
the voltage generator includes a plurality of pump circuits that is connected in series between the first node and the third node and that boosts the first external voltage, and
a first pump circuit connected to the third node among the pump circuits includes:
one or more charge transfer switches connected between the first node and the third node; and
one or more diode-connected transistors having diode-connection and connected in parallel to a charge transfer path of the charge transfer switch.

10. The memory device according to claim 9, wherein
the voltage generator includes:
a second pump circuit provided between the first node and the first pump circuit; and
a first switch provided between an input node of the first pump circuit and an output node of the second pump circuit.

11. The memory device according to claim 9, wherein
when the first pump circuit is stopped, the charge transfer path of the charge transfer switch is charged via the diode-connected transistor.

12. The memory device according to claim 9, wherein
the voltage generator further includes a first regulator that adjusts the second external voltage, and
the charge transfer path of the charge transfer switch is charged by a voltage supplied from the first regulator to the first pump circuit via the diode-connected transistor.

13. The memory device according to claim 9, wherein
the voltage generator further includes:
a second pump circuit provided between the first node and the first pump circuit;
a first switch provided between an input node of the first pump circuit and an output node of the second pump circuit;
a second regulator provided between an output node of the second pump circuit and the third node; and
a second switch connected between an output node of the second regulator and the input node of the first pump circuit.

14. The memory device according to claim 13, wherein
when the first switch is in an OFF state and the second switch is in an ON state,
the second regulator supplies a voltage from the second pump circuit to the charge transfer switch of the first pump circuit via the second switch in the ON state.

15. The memory device according to claim 9, wherein
the charge transfer switch includes:
a first well of a second conductivity type provided in a semiconductor substrate of a first conductivity type;
a second well of the first conductivity type provided in the first well;
first and second source/drain layers provided in the second well;
a first gate insulating film provided on a channel region between the first and second sources/drain layers; and
a first gate electrode provided on the first gate insulating film.

16. The memory device according to claim 9, further comprising:
a transfer gate connected to a word line of the memory cell array, wherein
a gate insulating film of the charge transfer switch is thinner than a gate insulating film of the transfer gate.

17. The memory device according to claim 9, wherein
the first pump circuit further includes a first capacitor,
the one or more charge transfer switches include a first charge transfer switch and a second charge transfer switch,
the one or more diode-connected transistors include a first diode-connected transistor and a second diode-connected transistor,
one end of a charge transfer path of the first charge transfer switch is connected to an input node of the first pump circuit, and the other end of the charge transfer path of the first charge transfer switch is connected to an internal node of the first pump circuit,
one end of a charge transfer path of the second charge transfer switch is connected to the internal node, and the other end of the charge transfer path of the second charge transfer switch is connected to an output node of the first pump circuit,
one end of the first diode-connected transistor is connected to the one end of the charge transfer path of the first charge transfer switch, the other end of the first diode-connected transistor is connected to the other end of the charge transfer path of the first charge transfer switch, and a gate of the first diode-connected transistor is connected to the one end of the first diode-connected transistor,
one end of the second diode-connected transistor is connected to the other end of the charge transfer path of the second charge transfer switch, the other end of the second diode-connected transistor is connected to the one end of the charge transfer path of the second charge transfer switch, and a gate of the second diode-connected transistor is connected to the one end of the second diode-connected transistor, and
one end of the first capacitor is connected to the internal node.

18. The memory device according to claim 17, wherein
the first pump circuit further includes a first transistor, a second transistor, a second capacitor, and a third capacitor,
the one or more diode-connected transistors further include a third diode-connected transistor,
one end of the first transistor is connected to the one end of the charge transfer path of the first charge transfer switch, and the other end of the first transistor is connected to a gate of the first charge transfer switch,
one end of the second transistor is connected to the other end of the charge transfer path of the second charge transfer switch, and the other end of the second transistor is connected to a gate of the second charge transfer switch,
one end of the third diode-connected transistor is connected to the one end of the charge transfer path of the first charge transfer switch, the other end of the third diode-connected transistor is connected to the gate of the first charge transfer switch, and a gate of the third diode-connected transistor is connected to the one end of the third diode-connected transistor,
one end of the second capacitor is connected to the gate of the first charge transfer switch, and
one end of the third capacitor is connected to the gate of the second charge transfer switch.

19. A memory device comprising:
a memory cell array including a plurality of memory cells; and
a voltage generator including a first node to which a first external voltage is supplied, a second node to which a second external voltage higher than the first external voltage is supplied, and a third node that outputs an operating voltage of the memory cell array, the voltage generator generating the operating voltage using at least one of the first and second external voltages, wherein
the voltage generator includes a plurality of pump circuits that boosts the first external voltage and is connected in series between the first node and the third node, and
at a time of generating the operating voltage using the second external voltage, the voltage generator charges a first pump circuit connected to the third node among the pump circuits.

20. The memory device according to claim 19, wherein
the voltage generator further includes a first regulator that adjusts the second external voltage, and
a charge transfer path of the first pump circuit is charged by a voltage output from the first regulator.
